(19) United States
(12) Patent Application Publication
(10) Pub. No.: US 2023/0317756 A1
(43) Pub. Date: Oct. 5, 2023

(54) IMAGE SENSOR

(71) Applicant: Samsung Electronics Co., Ltd., Suwon-si (KR)

(72) Inventors: Sangin BAE, Suwon-si (KR); BUMSUK KIM, Suwon-si (KR); YUN KI LEE, Suwon-si (KR); Cheon Ho PARK, Suwon-si (KR)

(21) Appl. No.: 18/125,018

(22) Filed: Mar. 22, 2023

(30) Foreign Application Priority Data
Apr. 5, 2022 (KR) 10-2022-0042125
Jul. 1, 2022 (KR) 10-2022-0081387

(51) Int. Cl. H01L 27/146

(52) U.S. Cl. CPC H01L 27/14627; H01L 27/14645; H01L 27/14621; H01L 27/14634; H01L 27/14636; H01L 27/1464

(57) ABSTRACT

An image sensor includes a first substrate including pixel regions, each of which comprises a photoelectric conversion region, color filters provided on the pixel regions, respectively, the color filters provided on a first surface of the first substrate, and micro lenses provided on the color filters, respectively. First period structures repeatedly arranged in a first direction are defined by the micro lenses. Each of the first period structures includes a first micro lens and a second micro lens of the micro lenses. At least one of a size, a curvature, a material or a shape of the first micro lens is different from at least one of a size, a curvature, a material or a shape of the second micro lens. A first arrangement period of the first period structures is equal to or greater than twice a pixel pitch of the pixel regions.

### CROSS-REFERENCE TO RELATED APPLICATIONS

This U.S. non-provisional patent application claims priority under 35 U.S.C. § 119 to Korean Patent Application Nos. 10-2022-0042125, filed on Apr. 5, 2022, and 10-2022-0081387, filed on Jul. 1, 2022, in the Korean Intellectual Property Office, the entire contents of both of which are hereby incorporated by reference.

### BACKGROUND OF THE INVENTION

The present disclosure relates to an image sensor, and more particularly, to an image sensor capable of improving quality of the output and a method of manufacturing the same.

An image sensor may be a device for converting an optical image into electrical signals. Image sensors may be categorized as any one of charge coupled device (CCD) image sensors and complementary metal-oxide-semiconductor (CMOS) image sensors. CIS is short for the CMOS image sensor. The CIS may include a plurality of pixels two-dimensionally arranged. Each of the pixels may include a photodiode (PD). The photodiode may convert incident light into an electrical signal.

### SUMMARY

Embodiments of the inventive concepts may provide an image sensor capable of improving quality of the output.

In an aspect, an image sensor may include a first substrate including pixel regions, each of the pixel regions comprising a photoelectric conversion region, color filters provided on the pixel regions, respectively, the color filters provided on a first surface of the first substrate, and micro lenses provided on the color filters, respectively. First period structures repeatedly arranged in a first direction may be defined by the micro lenses. Each of the first period structures may include a first micro lens and a second micro lens of the micro lenses. At least one of a size, a curvature, a material or a shape of the first micro lens may be different from at least one of a size, a curvature, a material or a shape of the second micro lens. A first arrangement period of the first period structures may be equal to or greater than twice a pixel pitch of the pixel regions.

In an aspect, an image sensor may include a substrate including pixel regions, each of the pixel regions comprising a photoelectric conversion region, color filters provided on the pixel regions, respectively, the color filters provided on a first surface of the substrate, and micro lenses provided on the color filters, respectively. First period structures repeatedly arranged in a first direction may be defined by the micro lenses. Second period structures repeatedly arranged in a second direction intersecting the first direction may be defined by the micro lenses. A first arrangement period of the first period structures may be equal to or greater than twice a pixel pitch of the pixel regions, and a second arrangement period of the second period structures may be equal to or greater than twice the pixel pitch.

In an aspect, an image sensor may include a circuit chip, and an image sensor chip stacked on the circuit chip. The image sensor chip may include a first substrate comprising photoelectric conversion regions therein and having a first surface and a second surface, which are opposite to each other, an isolation pattern provided in the first substrate to define pixel regions, the photoelectric conversion regions provided in the pixel regions, respectively, an insulating layer covering the first surface, color filters on the insulating layer, a fence pattern dividing the color filters, a protective layer between the fence pattern and the color filters, micro lenses provided on the color filters, respectively, a lens coating layer on the micro lenses, a device isolation pattern disposed adjacent to the second surface to define an active region, a buried gate pattern on the second surface, and a first interconnection layer on the buried gate pattern. The circuit chip may include a second substrate on which integrated circuits are provided, and a second interconnection layer on the second substrate. The first interconnection layer and the second interconnection layer may face each other and may be electrically connected to each other. First period structures repeatedly arranged in a first direction may be defined by the micro lenses. A first arrangement period of the first period structures may be equal to or greater than twice a pixel pitch of the pixel regions.

### BRIEF DESCRIPTION OF THE DRAWINGS

FIG. 1 is a circuit diagram of pixels of an image sensor according to some example embodiments of the inventive concepts.

FIG. 2 is a plan view illustrating an image sensor according to some example embodiments of the inventive concepts.

FIG. 3 is a cross-sectional view taken along a line I-I′ of FIG. 2 to illustrate an image sensor according to some example embodiments of the inventive concepts.

FIG. 4 is a cross-sectional view taken along the line I-I′ of FIG. 2 to illustrate an image sensor according to some example embodiments of the inventive concepts.

FIG. 5 is a cross-sectional view taken along a line II-IF of FIG. 2 to illustrate an image sensor according to some example embodiments of the inventive concepts.

FIG. 6 is an enlarged plan view of a region ‘IVY of FIG. 2 to illustrate an image sensor according to some example embodiments of the inventive concepts.

FIG. 7 is a cross-sectional view taken along a line I-I’ of FIG. 6 to illustrate an image sensor according to some example embodiments of the inventive concepts.

FIG. 8 is an enlarged plan view of the region ‘IVY of FIG. 2 to illustrate an image sensor according to some example embodiments of the inventive concepts.

FIG. 9 is a cross-sectional view taken along a line I-I’ of FIG. 8 to illustrate an image sensor according to some example embodiments of the inventive concepts.

FIG. 10 is an enlarged plan view of the region ‘IVY of FIG. 2 to illustrate an image sensor according to some example embodiments of the inventive concepts.

FIG. 11 is a cross-sectional view taken along a line I-I’ of FIG. 10 to illustrate an image sensor according to some example embodiments of the inventive concepts.

FIGS. 12, 13 and 14 are cross-sectional views illustrating differences between a first micro lens and a second micro lens according to some example embodiments of the inventive concepts.

FIG. 15 is an enlarged plan view of the region ‘IVY of FIG. 2 to illustrate an image sensor according to some example embodiments of the inventive concepts.

FIG. 16A is a cross-sectional view taken along a line I-I’ of FIG. 15 to illustrate an image sensor according to some example embodiments of the inventive concepts.

FIG. 16B is a cross-sectional view taken along a line II-IF of FIG. 15 to illustrate an image sensor according to some example embodiments of the inventive concepts.

FIG. 17 is an enlarged plan view of the region ‘M’ of FIG. 2 to illustrate an image sensor according to some example embodiments of the inventive concepts.

FIG. 18 is an enlarged plan view of the region ‘M’ of FIG. 2 to illustrate an image sensor according to some example embodiments of the inventive concepts.

FIG. 19 is a cross-sectional view taken along a line I-I’ of FIG. 18 to illustrate an image sensor according to some example embodiments of the inventive concepts.

FIGS. 20, 21 and 22 are plan views illustrating arrangements of color filters of image sensors according to some example embodiments of the inventive concepts.

### DETAILED DESCRIPTION

Hereinafter, one or more embodiments of the inventive concept will be described in detail with reference to the attached drawings. Like reference numerals denote like elements, and repeated descriptions thereof will be omitted. As used herein, the term “contact” refers to a direct connection (i.e., touching) unless the context indicates otherwise.

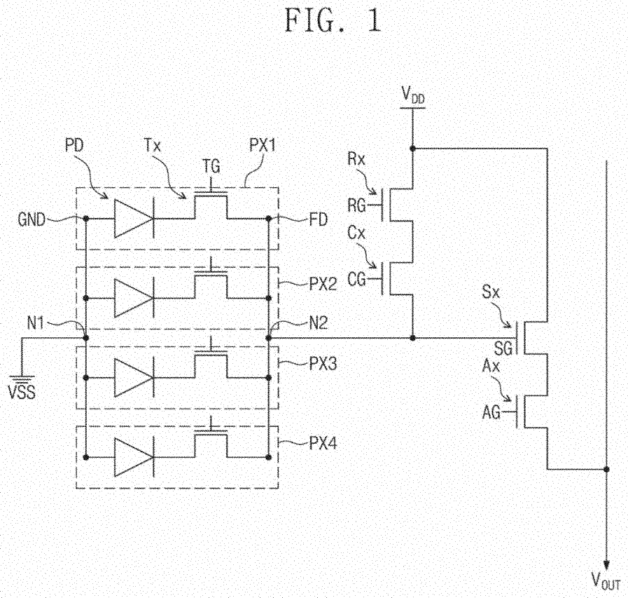

FIG. 1 is a circuit diagram of pixels of an image sensor according to some example embodiments of the inventive concepts.

Referring to FIG. 1, an image sensor may include first to fourth pixels PX1 to PX4. Each of the first to fourth pixels PX1 to PX4 may include a ground region GND, a photoelectric conversion region PD, a transfer transistor Tx, and a floating diffusion region FD.

The ground region GND may include a P-type dopant region. A ground voltage VSS may be applied in common to the ground regions GND of the first to fourth pixels PX1 to PX4 through a first node N1.

The photoelectric conversion region PD may be a photodiode including an N-type dopant region and a P-type dopant region. The floating diffusion region FD may include an N-type dopant region. The floating diffusion region FD may function as a drain of the transfer transistor Tx.

The floating diffusion regions FD of the first to fourth pixels PX1 to PX4 may be connected in common to a second node N2. The second node N2 to which the floating diffusion regions FD of the first to fourth pixels PX1 to PX4 are connected may be connected to a source of a conversion gain transistor Cx. The conversion gain transistor Cx may be connected to a reset transistor Rx.

The second node N2 may also be electrically connected to a source follower gate SG of a source follower transistor Sx. The source follower transistor Sx may be connected to a selection transistor Ax.

An operation of the image sensor will be described hereinafter with reference to FIG. 1. First, in a state in which light is blocked, a power voltage VDD may be applied to a drain of the reset transistor Rx and a drain of the source follower transistor Sx, and the reset transistor Rx may be turned-on to discharge charges remaining in the floating diffusion region FD. Thereafter, the reset transistor Rx may be turned-off, and external light may be incident to the photoelectric conversion region PD to generate electron-hole pairs in the photoelectric conversion region PD. The holes may be moved into and accumulated in the P-type dopant region of the photoelectric conversion region PD, and the electrons may be moved into and accumulated in the N-type dopant region of the photoelectric conversion region PD. The transfer transistor Tx may be turned-on to transfer charges (e.g., the electrons or the holes) into the floating diffusion region FD, and the transferred charges may be accumulated in the floating diffusion region FD. A gate bias of the source follower transistor Sx may be changed in proportion to the amount of the charges accumulated in the floating diffusion region FD, thereby causing a change in potential of a source of the source follower transistor Sx. At this time, the selection transistor Ax may be turned-on, and thus a signal generated by the charges may be read through a column line.

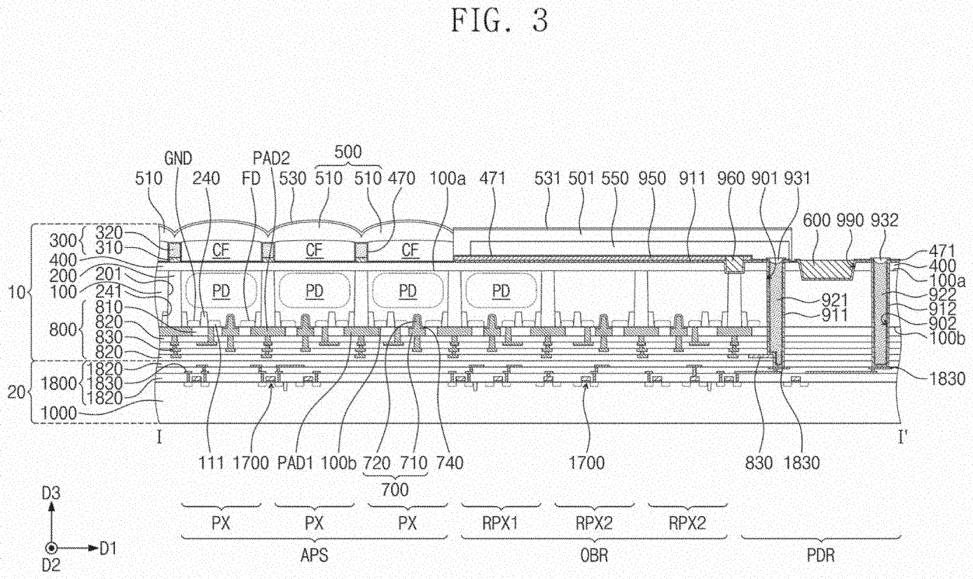

An interconnection line may be electrically connected to at least one of a transfer gate TG, the source follower gate SG, a reset gate RG, or a selection gate AG. The interconnection line may be configured to apply the power voltage VDD to the drain of the reset transistor Rx or the drain of the source follower transistor Sx. The interconnection line may include the column line connected to the selection transistor Ax. The interconnection line may include a first conductive structure 830 to be described later in FIG. 3.

FIG. 1 illustrates the first to fourth pixels PX1 to PX4 sharing the first node N1 and the second node N2, but embodiments of the inventive concepts are not limited thereto.

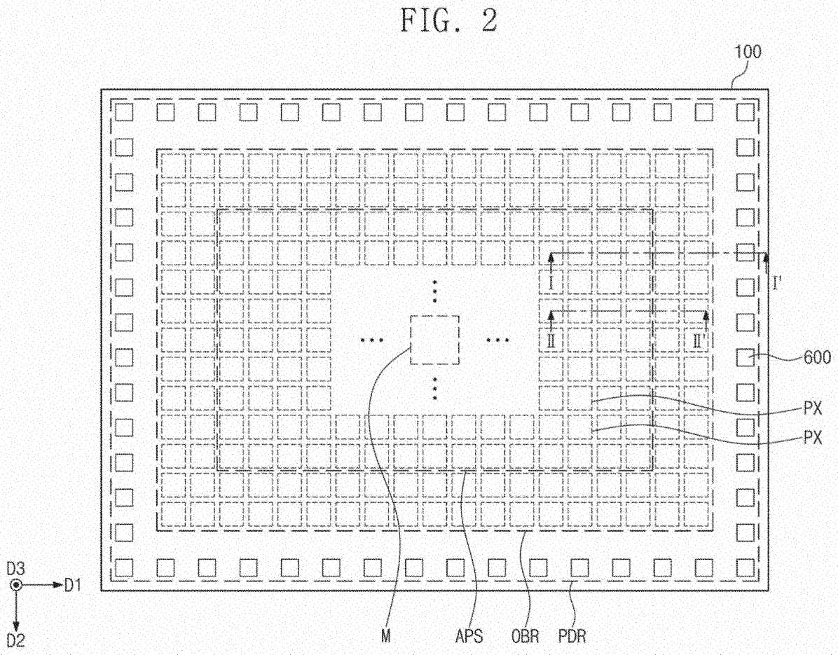

FIG. 2 is a plan view illustrating an image sensor according to some example embodiments of the inventive concepts. FIG. 3 is a cross-sectional view taken along a line I-I′ of FIG. 2.

Referring to FIGS. 2 and 3, an image sensor may include a sensor chip 10. The sensor chip 10 may include a first substrate 100, a first interconnection layer 800, an insulating layer 400, a protective layer 470, color filters CF, a fence pattern 300, and a micro lens layer 500.

The first substrate 100 may include a pixel array region APS, an optical black region OBR, and a pad region PDR when viewed in a plan view. The pixel array region APS may be disposed in a central region of the first substrate 100. The pixel array region APS may include a plurality of pixel regions PX. The pixels described with reference to FIG. 1 may be provided in the pixel regions PX of the first substrate 100, respectively. For example, the components of each of the pixels of FIG. 1 may be provided in each of the pixel regions PX. The pixel regions PX may output photoelectric signals from incident light.

The pixel regions PX may be two-dimensionally arranged to constitute rows and columns. The rows may be parallel to a first direction D1. The columns may be parallel to a second direction D2. In the present specification, the first direction D1 may be parallel to a first surface 100a of the first substrate 100. The second direction D2 may be parallel to the first surface 100a of the first substrate 100 and may intersect the first direction D1. For example, the second direction D2 may be substantially perpendicular to the first direction D1. A third direction D3 may be perpendicular to the first direction D1 and the second direction D2. For example, the third direction D3 may be substantially perpendicular to the first surface 100a of the first substrate 100.

The pad region PDR may be provided in an edge region of the first substrate 100 to surround the pixel array region APS. External connection pads 600 may be provided on the pad region PDR. The external connection pads 600 may output electrical signals generated from the pixel regions PX to the outside. In addition, an external electrical signal or voltage may be transmitted to the pixel regions PX through the external connection pads 600. Since the pad region PDR is disposed in the edge region of the first substrate 100, the external connection pads 600 may be easily connected to an external device. The optical black region OBR will be described later in detail. Hereinafter, the pixel array region APS of the sensor chip 10 of the image sensor will be described in more detail.

The first substrate 100 may have the first surface 100a and a second surface 100b which are opposite to each other. The first surface 100a of the first substrate 100 may be a back surface, and the second surface 100b of the first substrate 100 may be a front surface. Light may be incident to the first surface 100a of the first substrate 100. The first substrate 100 may be a semiconductor substrate or a silicon-on-insulator (SOI) substrate. For example, the semiconductor substrate may include a silicon substrate, a germanium substrate, or a silicon-germanium substrate. The first substrate 100 may further include a group III element. The group III element may be dopants having a first conductivity type. In other words, the first substrate 100 may have the first conductivity type (e.g., a P-type). For example, the dopants having the first conductivity type may include aluminum (Al), boron (B), indium (In), and/or gallium (Ga).

The first substrate 100 may include a plurality of photoelectric conversion regions PD therein. The photoelectric conversion regions PD may be located between the first surface 100a and the second surface 100b of the first substrate 100. The photoelectric conversion regions PD may be provided in the pixel regions PX of the first substrate 100, respectively. The photoelectric conversion region PD of FIG. 3 may correspond to the photoelectric conversion region PD of FIG. 1.

The photoelectric conversion region PD may further include a group V element. The group V element may be dopants having a second conductivity type. In other words, the photoelectric conversion region PD may be a dopant region having the second conductivity type. The second conductivity type may be an N-type different from the first conductivity type. The dopants having the second conductivity type may include phosphorus, arsenic, bismuth, and/or antimony. The photoelectric conversion region PD may be adjacent to the first surface 100a of the first substrate 100. The photoelectric conversion region PD may extend from the first surface 100a toward the second surface 100b.

An isolation pattern 200 may be provided in the first substrate 100 to define the pixel regions PX. For example, the isolation pattern 200 may be provided between the pixel regions PX adjacent to each other. The isolation pattern 200 may be a pixel isolation pattern. The isolation pattern 200 may be provided in a first trench 201. The first trench 201 may be recessed from the second surface 100b toward the first surface 100a of the first substrate 100.

The isolation pattern 200 may be a deep trench isolation (DTI) pattern. In the present embodiments, the isolation pattern 200 may penetrate the first substrate 100. For example, the isolation pattern 200 may extend from the second surface 100b to the first surface 100a. In such embodiments, a thickness in the third direction D3 of the isolation pattern 200 may be the same as a thickness in the third direction D3 of the first substrate 100. In certain embodiments, the isolation pattern 200 may not penetrate the first substrate 100 but may be spaced apart from the first surface 100a of the first substrate 100. For example, the isolation pattern 200 may extend from the second surface 100b in the direction of the first surface 100a. In such embodiments, a thickness in the third direction D3 of the isolation pattern 200 may be less than a thickness in the third direction D3 of the first substrate 100. A width in the first direction D1 of the isolation pattern 200 adjacent to the second surface 100b may be greater than a width in the first direction D1 of the isolation pattern 200 adjacent to the first surface 100a.

The color filters CF may be disposed on the first surface 100a of the first substrate 100 and may be disposed on the pixel regions PX, respectively. For example, the color filters CF may be provided at positions corresponding to the photoelectric conversion regions PD, respectively. In some embodiments, each of the color filters CF may include one of a red filter, a blue filter, and a green filter. The color filters CF may constitute a color filter array. For example, the color filters CF may be two-dimensionally arranged in the form of a Bayer pattern.

In certain embodiments, the color filters CF may further include a white filter. For example, the color filters CF may include the red filters, the blue filters, the green filters and the white filters, which are two-dimensionally arranged.

The fence pattern 300 may be disposed on the isolation pattern 200. For example, the fence pattern 300 may vertically overlap with the isolation pattern 200. The fence pattern 300 may be disposed between two adjacent color filters CF to separate the color filters CF from each other. For example, the color filters CF may be physically and optically separated from each other by the fence pattern 300.

The fence pattern 300 may have a planar shape corresponding to that of the isolation pattern 200. For example, the fence pattern 300 may have a grid shape. The fence pattern 300 may surround each of the pixel regions PX when viewed in a plan view. The fence pattern 300 may surround each of the color filters CF. The fence pattern 300 may include first portions and second portions. The first portions may extend in parallel to the first direction D1 and may be spaced apart from each other in the second direction D2. The second portions may extend in parallel to the second direction D2 and may be spaced apart from each other in the first direction D1. The second portions may intersect the first portions.

The fence pattern 300 may include a first fence pattern 310 and a second fence pattern 320. The first fence pattern 310 may be disposed between the insulating layer 400 and the second fence pattern 320. For example, the first fence pattern 310 may contact an upper surface of the insulating layer 400 and a bottom surface of the second fence pattern 320. The first fence pattern 310 may include a conductive material such as a metal and/or a metal nitride. For example, the first fence pattern 310 may include titanium and/or titanium nitride.

The second fence pattern 320 may be disposed on the first fence pattern 310. The second fence pattern 320 may include a different material from that of the first fence pattern 310. The second fence pattern 320 may include an organic material. The second fence pattern 320 may include a low-refractive index material and may have an insulating property.

The insulating layer 400 may be disposed between the first substrate 100 and the color filters CF and between the isolation pattern 200 and the fence pattern 300. The insulating layer 400 may cover the first surface 100a of the first substrate 100 and a top surface of the isolation pattern 200. For example, the insulating layer 400 may contact the first surface 100a of the first substrate 100 and the top surface of the isolation pattern 200.

The insulating layer 400 may be a backside insulating layer. The insulating layer 400 may include a bottom anti-reflective coating (BARC) layer. The insulating layer 400 may include a plurality of layers, and the layers of the insulating layer 400 may perform different functions.

In some embodiments, the insulating layer 400 may include a first insulating layer, a second insulating layer, a third insulating layer, a fourth insulating layer, and a fifth insulating layer, which are sequentially stacked on the first surface 100a of the first substrate 100. The first insulating layer may cover the first surface 100a of the first substrate 100. The first and second insulating layers may be fixed charge layers. Each of the fixed charge layers may be formed of a metal oxide layer or a metal fluoride layer. The metal oxide layer may include insufficient oxygen in terms of a stoichiometric ratio, and the metal fluoride layer may include insufficient fluorine in terms of a stoichiometric ratio.

For example, the first insulating layer may be formed of a metal oxide layer or metal fluoride layer including at least one metal selected from a group consisting of hafnium (Hf), zirconium (Zr), aluminum (Al), tantalum (Ta), titanium (Ti), yttrium (Y), and a lanthanoid. The second insulating layer may include the metal oxide layer or metal fluoride layer described as the examples of the first insulating layer. However, the second insulating layer may include a different material from that of the first insulating layer. For example, the first insulating layer may include an aluminum oxide layer, and the second insulating layer may include a hafnium oxide layer.

Each of the first and second insulating layers may have negative fixed charges and may accumulate holes. A dark current and a white spot of the first substrate 100 may be effectively reduced by the first and second insulating layers. A thickness of the second insulating layer may be greater than a thickness of the first insulating layer.

The third insulating layer may be disposed on the second insulating layer. The third insulating layer may include a first silicon-containing material. For example, the first silicon-containing material may include tetraethyl orthosilicate (TEOS) or silicon oxide. The third insulating layer may have a good filling property. For example, the third insulating layer may be formed by, but not limited to, a plasma-enhanced chemical vapor deposition (CVD) method. A thickness of the third insulating layer may be greater than the thickness of the first insulating layer and may be greater than the thickness of the second insulating layer.

The fourth insulating layer may be disposed on the third insulating layer. The fourth insulating layer may include a different material from that of the third insulating layer. The fourth insulating layer may include a second silicon-containing material different from the first silicon-containing material. For example, the fourth insulating layer may include silicon nitride. A thickness of the fourth insulating layer may be greater than the thickness of the third insulating layer.

The fifth insulating layer may be disposed between the fourth insulating layer and the first fence pattern 310 and between the fourth insulating layer and the color filters CF. The fifth insulating layer may be in physical contact with a bottom surface of the first fence pattern 310. The fifth insulating layer may be an adhesive layer or a capping layer. The fifth insulating layer may include a high-k dielectric material or a metal oxide. The fifth insulating layer may include the same material as the second insulating layer. For example, the fifth insulating layer may include hafnium oxide. A thickness of the fifth insulating layer may be greater than the thicknesses of the first and second insulating layers and may be less than the thicknesses of the third and fourth insulating layers.

Unlike the examples described above in detail, the number of the layers of the insulating layer 400 may be variously changed. For example, at least one of the first to fifth insulating layers may be omitted.

The protective layer 470 may cover the insulating layer 400 and the fence pattern 300. The protective layer 470 may include a high-k dielectric material and may have an insulating property. For example, the protective layer 470 may include aluminum oxide or hafnium oxide. Particularly, the protective layer 470 may include aluminum oxide, but embodiments of the inventive concepts are not limited thereto. The protective layer 470 may protect the photoelectric conversion regions PD of the first substrate 100 from an external environment such as moisture.

The color filters CF may be provided on the protective layer 470. The color filters CF may be spaced apart from each other by the fence pattern 300. A topmost surface of the color filter CF may be coplanar with a top surface of the fence pattern 300. In certain embodiments, the topmost surface of the color filter CF may be higher than the top surface of the fence pattern 300.

The micro lens layer 500 may be provided on the first surface 100a of the first substrate 100. For example, the micro lens layer 500 may be provided on the color filters CF. The protective layer 470 may be disposed between the second fence pattern 320 and the micro lens layer 500.

The micro lens layer 500 may include a plurality of convex micro lenses 510. The micro lenses 510 may be provided at positions corresponding to the photoelectric conversion regions PD of the first substrate 100, respectively. For example, the micro lenses 510 may be provided on the color filters CF, respectively, and may correspond to the color filters CF, respectively. The micro lenses 510 may be arranged in the first direction D1 and the second direction D2 to constitute an array when viewed in a plan view. Each of the micro lenses 510 may protrude in a direction away from the first surface 100a of the first substrate 100. Each of the micro lenses 510 may have a hemispherical cross section. The micro lenses 510 may concentrate incident light.

The micro lens layer 500 may be transparent to transmit light. The micro lens layer 500 may include an organic material such as a polymer. For example, the micro lens layer 500 may include a photoresist material or a thermosetting resin.

A lens coating layer 530 may be provided on the micro lens layer 500. The lens coating layer 530 may be transparent. The lens coating layer 530 may conformally cover a top surface of the micro lens layer 500. The lens coating layer 530 may protect the micro lens layer 500.

The first substrate 100 may include a ground region GND, a floating diffusion region FD, and a dopant region 111, which are adjacent to the second surface 100b. The ground region GND, the floating diffusion region FD, and the dopant region 111 may be disposed in each of the pixel regions PX. A bottom surface of each of the ground region GND, the floating diffusion region FD, and the dopant region 111 may be vertically spaced apart from the photoelectric conversion region PD.

The ground region GND may be heavily doped with dopants to have the first conductivity type (e.g., a P-type). Each of the floating diffusion region FD and the dopant region 111 may be doped with dopants to have the second conductivity type (e.g., an N-type).

The dopant region 111 may be a dopant region for operation of a transistor. The dopant region 111 may include source/drain regions of at least one of the conversion gain transistor Cx, the reset transistor Rx, the source follower transistor Sx, and the selection transistor Ax, described above with reference to FIG. 1.

A device isolation pattern 240 may be provided to be adjacent to the second surface 100b of the first substrate 100. The device isolation pattern 240 may define an active region in the pixel region PX. More particularly, in the pixel region PX, the device isolation pattern 240 may define the ground region GND, the floating diffusion region FD, and the dopant region 111.

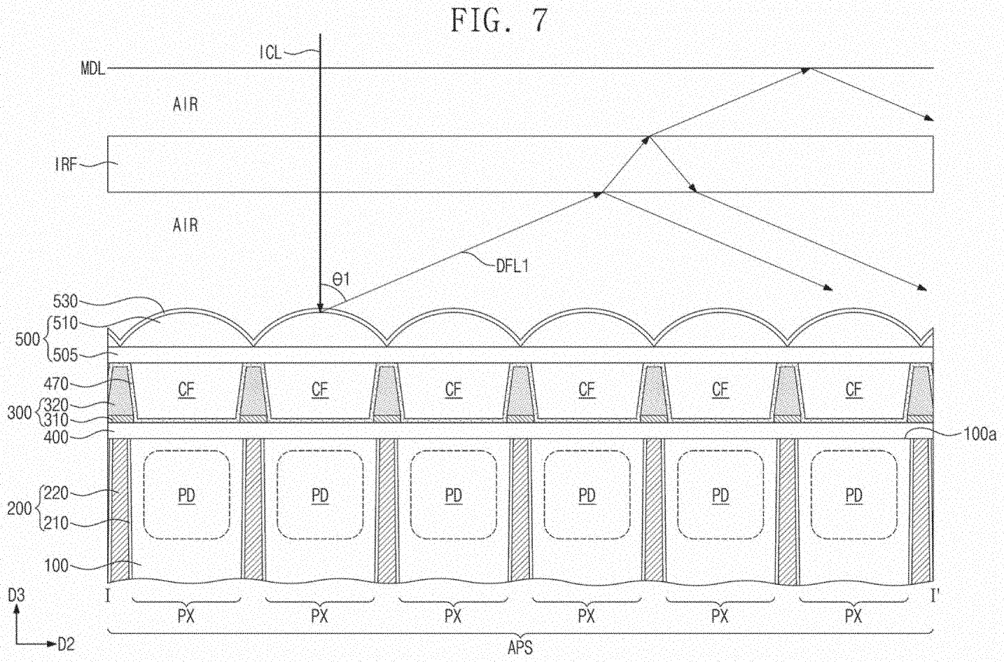

The device isolation pattern 240 may be provided in a second trench 241, and the second trench 241 may be recessed from the second surface 100b of the first substrate 100. The device isolation pattern 240 may be a shallow trench isolation (STI) pattern. A depth of the device isolation pattern 240 may be less than a depth of the isolation pattern 200. A portion of the device isolation pattern 240 may be connected to a sidewall of a first isolation pattern 210 to be described later in FIG. 7. For example, the device isolation pattern 240 may include at least one of silicon oxide, silicon nitride, or silicon oxynitride.

A buried gate pattern 700 may be provided on the second surface 100b of the first substrate 100. The buried gate pattern 700 may include the transfer gate TG of the transfer transistor Tx described above in FIG. 1. Although not shown in FIG. 3, at least one additional gate pattern may be provided on each of the pixel regions PX.

The additional gate pattern may function as a gate electrode of at least one of the conversion gain transistor Cx, the source follower transistor Sx, the reset transistor Rx, and the selection transistor Ax, described above with reference to FIG. 1. For example, the additional gate pattern may include the conversion gain gate CG, the source follower gate SG, the reset gate RG, or the selection gate AG.

The buried gate pattern 700 may have a buried gate structure. For example, the buried gate pattern 700 may include a first portion 710 and a second portion 720. The first portion 710 of the buried gate pattern 700 may be disposed on the second surface 100b of the first substrate 100. The second portion 720 of the buried gate pattern 700 may be buried in the first substrate 100. The second portion 720 of the buried gate pattern 700 may be connected to the first portion 710. The first portion 710 and the second portion 720 may be in material continuity with one another. For example, the first portion 710 and the second portion 720 may be formed at the same time and of the same material, without a break in the continuity of the material of which they are formed. Unlike FIG. 3, the buried gate pattern 700 may have a planar gate structure. In this case, the buried gate pattern 700 may not include the second portion 720. The buried gate pattern 700 may include a metal, a metal silicide, poly-silicon, or any combination thereof. Here, the poly-silicon may include doped poly-silicon.

A gate insulating pattern 740 may be disposed between the buried gate pattern 700 and the first substrate 100. For example, the gate insulating pattern 740 may include a silicon-based insulating material (e.g., silicon oxide, silicon nitride, and/or silicon oxynitride) and/or a high-k dielectric material (e.g., hafnium oxide and/or aluminum oxide).

A first pad PAD1 may be provided on the ground region GND. The first pad PAD1 may be provided on the ground regions GND of the pixel regions PX adjacent to each other to electrically connect the ground regions GND to each other. The first pad PAD1 may include the first node N1 described with reference to FIG. 1.

A second pad PAD2 may be provided on the floating diffusion region FD. The second pad PAD2 may be provided on the floating diffusion regions FD of the pixel regions PX adjacent to each other to electrically connect the floating diffusion regions FD to each other. The second pad PAD2 may include the second node N2 described with reference to FIG. 1.

The first and second pads PAD1 and PAD2 may include a metal, a metal silicide, poly-silicon, or any combination thereof. For example, the first and second pads PAD1 and PAD2 may include doped poly-silicon.

The first interconnection layer 800 may be disposed on the second surface 100b of the first substrate 100. The first interconnection layer 800 may include a first interlayer insulating layer 810, second interlayer insulating layers 820, and a first conductive structure 830. The first interlayer insulating layer 810 may cover the second surface 100b of the first substrate 100 and the buried gate pattern 700. The second interlayer insulating layers 820 may be stacked on the first interlayer insulating layer 810. For example, each of the first and second interlayer insulating layers 810 and 820 may include a silicon-based insulating material such as silicon oxide, silicon nitride, and/or silicon oxynitride.

The first conductive structure 830 may be provided in the first and second interlayer insulating layers 810 and 820. The first conductive structure 830 may include contacts, interconnection lines, and vias. The contact may be provided in the first and second interlayer insulating layers 810 and 820 adjacent to the second surface 100b so as to be connected to at least one of the buried gate pattern 700, the first and second pads PAD1 and PAD2, and the dopant region 111. The interconnection line of the first conductive structure 830 may be connected to the contact. The via of the first conductive structure 830 may penetrate at least one of the second interlayer insulating layers 820 and may connect the interconnection lines vertically adjacent to each other. The first conductive structure 830 may receive photoelectric signals outputted from the photoelectric conversion regions PD.

Hereinafter, a circuit chip 20 of the image sensor and the optical black region OBR and the pad region PDR of the first substrate 100 will be described in detail. Referring again to FIGS. 2 and 3, the optical black region OBR of the first substrate 100 may be disposed between the pixel array region APS and the pad region PDR. The optical black region OBR may include a first reference pixel region RPX1 and a second reference pixel region RPX2. The first reference pixel region RPX1 may be disposed between the second reference pixel region RPX2 and the pixel array region APS. In some embodiments, the first reference pixel region RPX1 may be provided between a plurality of second reference pixel region RPX2 and the pixel array region APS. In the optical black region OBR, the photoelectric conversion region PD may be provided in the first reference pixel region RPX1. The photoelectric conversion region PD of the first reference pixel region RPX1 may have the same planar area and volume as the photoelectric conversion regions PD of the pixel regions PX. The photoelectric conversion region PD may not be provided in the second reference pixel region RPX2. The dopant region 111, the buried gate pattern 700, and the device isolation pattern 240 may be disposed in each of the first and second reference pixel regions RPX1 and RPX2.

The insulating layer 400 may extend from the pixel array region APS onto the pad region PDR via the optical black region OBR. A light blocking layer 950 may be provided on the optical black region OBR. The light blocking layer 950 may be disposed on a top surface of the insulating layer 400. Due to the light blocking layer 950, light may not be incident to the photoelectric conversion region PD of the optical black region OBR. Pixels of the first and second reference pixel regions RPX1 and RPX2 of the optical black region OBR may not output photoelectric signals but may output noise signals. The noise signal may be generated by electrons generated by occurrence of heat or a dark current. Since the light blocking layer 950 does not cover the pixel array region APS, light may be incident to the photoelectric conversion regions PD of the pixel array region APS. The noise signal may be removed from photoelectric signals outputted from the pixel regions PX. For example, the light blocking layer 950 may include a metal such as tungsten, copper, aluminum, or any alloy thereof.

In the optical black region OBR of the first substrate 100, a first conductive pattern 911 may be disposed between the insulating layer 400 and the light blocking layer 950. The first conductive pattern 911 may function as a barrier layer or an adhesive layer. The first conductive pattern 911 may include a metal and/or a metal nitride. For example, the first conductive pattern 911 may include a metal such as copper, tungsten, aluminum, titanium, tantalum, or any alloy thereof. The first conductive pattern 911 may not extend onto the pixel array region APS of the first substrate 100.

In the optical black region OBR of the first substrate 100, a contact plug 960 may be provided on the first surface 100a of the first substrate 100. The contact plug 960 may be disposed on an outermost isolation pattern 200 in the optical black region OBR. A contact trench penetrating the insulating layer 400 may be defined on the first surface 100a of the first substrate 100, and the contact plug 960 may be provided in the contact trench.

The contact plug 960 may include a different material from that of the light blocking layer 950. For example, the contact plug 960 may include a metal material such as aluminum. The first conductive pattern 911 may extend between the contact plug 960 and the insulating layer 400 and between the contact plug 960 and the isolation pattern 200. The first conductive pattern 911 may contact side and lower surfaces of the contact plug 960 and upper surfaces of the insulating layer 400 and the isolation pattern 200.

A protective insulating layer 471 may be provided on the optical black region OBR. The protective insulating layer 471 may be disposed on a top surface of the light blocking layer 950 and a top surface of the contact plug 960. The protective insulating layer 471 may contact the top surfaces of the light blocking layer 950 and the contact plug 960. The protective insulating layer 471 may include the same material as the protective layer 470 and may be connected to the protective layer 470. The protective insulating layer 471 and the protective layer 470 may be formed in one body. For example, the protective insulating layer 471 and the protective layer 470 may be formed at the same time and of the same material, without a break in the continuity of the material of which they are formed. In certain embodiments, the protective insulating layer 471 may be formed by a different process from a process of forming the protective layer 470 and may be spaced apart from the protective layer 470. The protective insulating layer 471 may include a high-k dielectric material (e.g., aluminum oxide and/or hafnium oxide).

A filtering layer 550 may be disposed on the first surface 100a of the optical black region OBR. The filtering layer 550 may cover a top surface of the protective insulating layer 471. For example, the filtering layer 550 may contact the top surface of the protective insulating layer 471. The filtering layer 550 may block light having a different wavelength from those of the color filters CF. For example, the filtering layer 550 may block infrared light. The filtering layer 550 may include, but not be limited to, a blue color filter.

An organic layer 501 may be provided on a top surface of the filtering layer 550. In some embodiments, the organic layer 501 may contact the top and side surfaces of the filtering layer 550. The organic layer 501 may be transparent. A top surface of the organic layer 501 may be substantially flat. For example, the organic layer 501 may include a polymer. The organic layer 501 may have an insulating property. In certain embodiments, unlike FIG. 3, the organic layer 501 may be connected to the micro lens layer 500. The organic layer 501 may include the same material as the micro lens layer 500.

A coating layer 531 may be provided on the organic layer 501. The coating layer 531 may conformally cover a top surface of the organic layer 501. The coating layer 531 may contact the top surface of the organic layer 501. The coating layer 531 may include an insulating material and may be transparent. The coating layer 531 may include the same material as the lens coating layer 530.

The image sensor may further include a circuit chip 20. The circuit chip 20 may be stacked on the sensor chip 10. The circuit chip 20 may include a second interconnection layer 1800 and a second substrate 1000. The second interconnection layer 1800 may be disposed between the first interconnection layer 800 and the second substrate 1000. Integrated circuits 1700 may be disposed on a top surface of the second substrate 1000 and/or in the second substrate 1000. The integrated circuits 1700 may include logic circuits, memory circuits, or a combination thereof. For example, the integrated circuits 1700 may include transistors.

The second interconnection layer 1800 may include third interlayer insulating layers 1820 and second conductive structures 1830. The second conductive structures 1830 may be provided between the third interlayer insulating layers 1820 and/or in the third interlayer insulating layers 1820. The second conductive structures 1830 may be electrically connected to the integrated circuits 1700. The second interconnection layer 1800 may further include a via pattern, and the via pattern may be connected to the second conductive structures 1830 in the third interlayer insulating layers 1820.

The external connection pad 600 may be provided on the pad region PDR of the first substrate 100. The external connection pad 600 may be adjacent to the first surface 100a of the first substrate 100. The external connection pad 600 may be buried in the first substrate 100. For example, a pad trench 990 may be defined in the first surface 100a of the first substrate 100 of the pad region PDR, and the external connection pad 600 may be provided in the pad trench 990. The external connection pad 600 may include a metal such as aluminum, copper, tungsten, titanium, tantalum, or any alloy thereof. In a mounting process of the image sensor, a bonding wire may be formed on the external connection pad 600 and may be connected to the external connection pad 600. The external connection pad 600 may be electrically connected to an external device through the bonding wire.

A first through-hole 901 may be defined to be adjacent to a first side of the external connection pad 600. The first through-hole 901 may be provided between the external connection pad 600 and the contact plug 960. The first through-hole 901 may penetrate the insulating layer 400, the first substrate 100, and the first interconnection layer 800. The first through-hole 901 may further penetrate at least a portion of the second interconnection layer 1800. The first through-hole 901 may have a first bottom surface and a second bottom surface. The first bottom surface of the first through-hole 901 may expose the first conductive structure 830. The second bottom surface of the first through-hole 901 may be disposed at a lower level than the first bottom surface. The second bottom surface of the first through-hole 901 may expose the second conductive structure 1830.

The first conductive pattern 911 may extend from the optical black region OBR onto the pad region PDR. The first conductive pattern 911 may cover an inner surface of the first through-hole 901. The first conductive pattern 911 in the first through-hole 901 may be in contact with a top surface of the first conductive structure 830. Thus, the first conductive structure 830 may be electrically connected to a second isolation pattern 220 to be described later in FIG. 7 through the first conductive pattern 911.

The first conductive pattern 911 in the first through-hole 901 may also be connected to a top surface of the second conductive structure 1830. The second conductive structure 1830 may be electrically connected to the first conductive structure 830 and the second isolation pattern 220 through the first conductive pattern 911.

A first filling pattern 921 may be provided in the first through-hole 901 to fill the first through-hole 901. The first filling pattern 921 may include a low-refractive index material and may have an insulating property. The first filling pattern 921 may include the same material as the second fence pattern 320. A top surface of the first filling pattern 921 may have a recess. For example, a center of the top surface of the first filling pattern 921 may be lower than an edge of the top surface of the first filling pattern 921.

A first capping pattern 931 may be disposed on the top surface of the first filling pattern 921 to fill the recess. A top surface of the first capping pattern 931 may be substantially flat. The first capping pattern 931 may include an insulating polymer such as a photoresist material.

A second through-hole 902 may be defined to be adjacent to a second side of the external connection pad 600. The second through-hole 902 may penetrate the insulating layer 400, the first substrate 100, and the first interconnection layer 800. The second through-hole 902 may penetrate a portion of the second interconnection layer 1800 to expose the second conductive structure 1830.

A second conductive pattern 912 may be provided on the pad region PDR. The second conductive pattern 912 may be provided in the second through-hole 902 to conformally cover an inner sidewall and a bottom surface of the second through-hole 902. The second conductive pattern 912 may be electrically connected to the second conductive structure 1830.

The second conductive pattern 912 may extend between the external connection pad 600 and an inner surface of the pad trench 990 to cover a bottom surface and a sidewall of the external connection pad 600. When the image sensor operates, the integrated circuits 1700 of the circuit chip 20 may transmit/receive electrical signals through the second conductive structure 1830, the second conductive pattern 912, and the external connection pad 600.

A second filling pattern 922 may be provided in the second through-hole 902 to fill the second through-hole 902. The second filling pattern 922 may include a low-refractive index material and may have an insulating property. For example, the second filling pattern 922 may include the same material as the second fence pattern 320. A top surface of the second filling pattern 922 may have a recess.

A second capping pattern 932 may be disposed on the top surface of the second filling pattern 922 to fill the recess. A top surface of the second capping pattern 932 may be substantially flat. The second capping pattern 932 may include an insulating polymer such as a photoresist material.

The protective insulating layer 471 may extend from the optical black region OBR onto the pad region PDR. The protective insulating layer 471 may be provided on the top surface of the insulating layer 400 and may extend into the first through-hole 901 and the second through-hole 902. The protective insulating layer 471 may be disposed between the first conductive pattern 911 and the first filling pattern 921 in the first through-hole 901.

The protective insulating layer 471 may be disposed between the second conductive pattern 912 and the second filling pattern 922 in the second through-hole 902. The protective insulating layer 471 may expose the external connection pad 600.

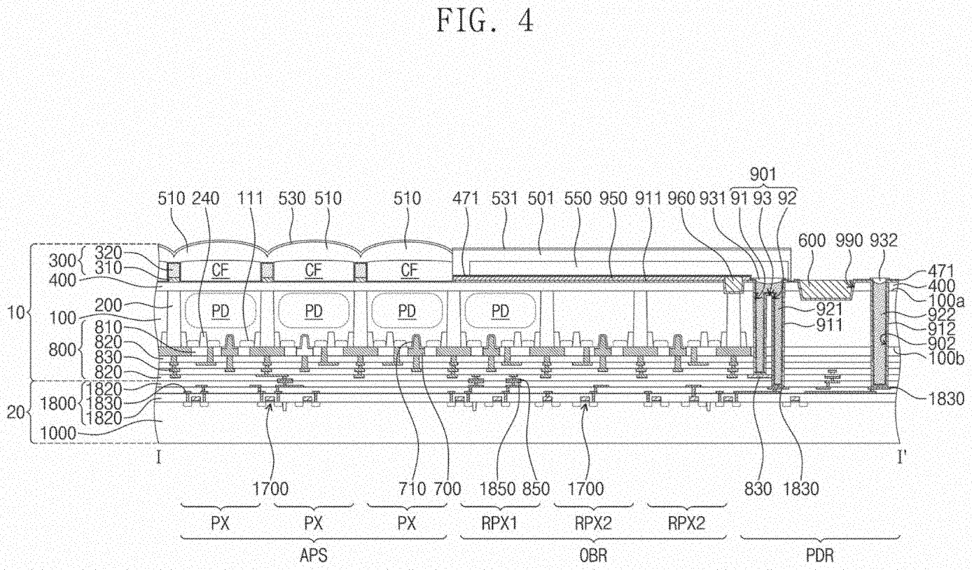

FIG. 4 is a cross-sectional view taken along the line I-I′ of FIG. 2 to illustrate an image sensor according to some example embodiments of the inventive concepts. In the present embodiments, the descriptions to the same technical features as mentioned above with reference to FIGS. 1 to 3 will be omitted and differences between the present embodiments and the above embodiments of FIGS. 1 to 3 will be mainly described, for the purpose of ease and convenience in explanation.

Referring to FIGS. 2 and 4, an image sensor may include a sensor chip 10 and a circuit chip 20. The sensor chip 10 may include a first connection pad 850. The first connection pad 850 may be exposed at a bottom surface of the sensor chip 10. The first connection pad 850 may be disposed in a lowermost second interlayer insulating layer 820. The first connection pad 850 may be electrically connected to the first conductive structure 830. The first connection pad 850 may include a conductive material such as a metal. For some examples, the first connection pad 850 may include copper. For certain examples, the first connection pad 850 may include aluminum, tungsten, titanium, and/or any alloy thereof.

The circuit chip 20 may include a second connection pad 1850. The second connection pad 1850 may be exposed at a top surface of the circuit chip 20. The second connection pad 1850 may be disposed in an uppermost third interlayer insulating layer 1820.

The second connection pad 1850 may be electrically connected to the integrated circuits 1700. The second connection pad 1850 may include a conductive material such as a metal. For some examples, the second connection pad 1850 may include copper. For certain examples, the second connection pad 1850 may include aluminum, tungsten, titanium, and/or any alloy thereof.

The circuit chip 20 may be connected to the sensor chip 10 by direct bonding. For example, the first connection pad 850 and the second connection pad 1850 may be vertically aligned with each other, and the first connection pad 850 and the second connection pad 1850 may be in contact with each other. Thus, the second connection pad 1850 may be bonded directly to the first connection pad 850. As a result, the integrated circuits 1700 of the circuit chip 20 may be electrically connected to the transistors and/or the external connection pad 600 of the sensor chip 10 through the first and second connection pads 850 and 1850.

The second interlayer insulating layer 820 may be adhered directly to the third interlayer insulating layer 1820. In this case, chemical bonds may be formed between the second interlayer insulating layer 820 and the third interlayer insulating layer 1820.

A first through-hole 901 may include a first through-hole portion 91, a second through-hole portion 92, and a third through-hole portion 93. The first through-hole portion 91 may penetrate the insulating layer 400, the first substrate 100, and the first interconnection layer 800 and may have a first bottom surface. The second through-hole portion 92 may penetrate the insulating layer 400, the first substrate 100, and the first interconnection layer 800 and may extend into an upper portion of the second interconnection layer 1800. The second through-hole portion 92 may have a second bottom surface exposing a top surface of the second conductive structure 1830. A sidewall of the second through-hole portion 92 may be spaced apart from a sidewall of the first through-hole portion 91. The third through-hole portion 93 may be provided between an upper portion of the first through-hole portion 91 and an upper portion of the second through-hole portion 92 and may be connected to the upper portion of the first through-hole portion 91 and the upper portion of the second through-hole portion 92. The first conductive pattern 911, the protective insulating layer 471 and the first filling pattern 921 may be provided in the first through-hole 901. The first conductive pattern 911 may cover inner surfaces of the first through-hole portion 91, the second through-hole portion 92 and the third through-hole portion 93.

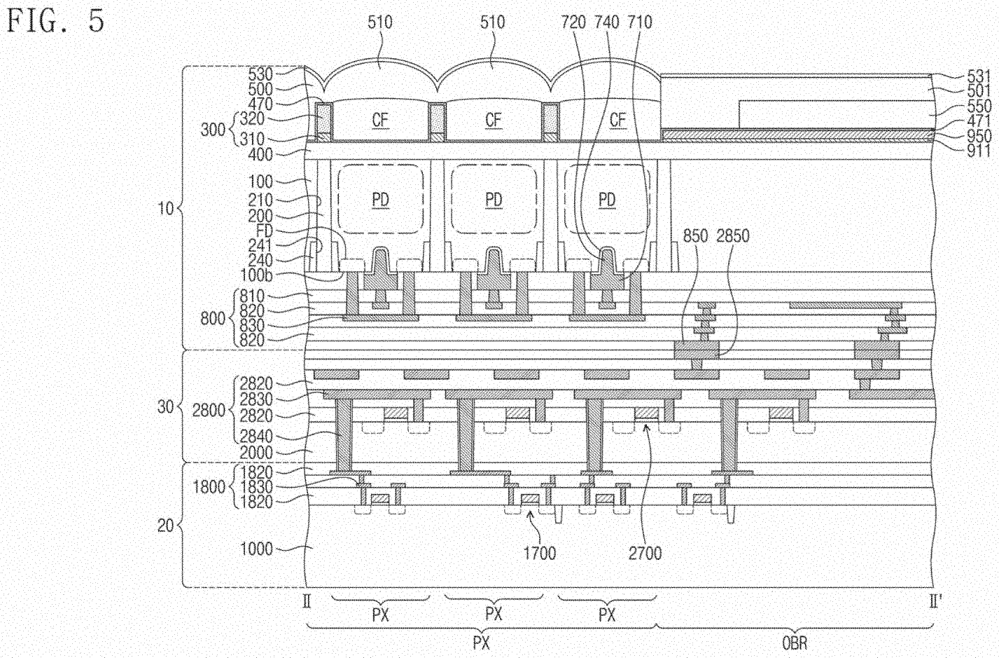

FIG. 5 is a cross-sectional view taken along a line II-IF of FIG. 2 to illustrate an image sensor according to some example embodiments of the inventive concepts. In the present embodiments, the descriptions to the same technical features as mentioned above with reference to FIGS. 1 to 4 will be omitted and differences between the present embodiments and the above embodiments of FIGS. 1 to 4 will be mainly described, for the purpose of ease and convenience in explanation.

Referring to FIGS. 2 and 5, an image sensor may further include an intermediate chip disposed between the sensor chip 10 and the circuit chip 20. The intermediate chip 30 may include a third interconnection layer 2800 and a third substrate 2000. The third interconnection layer 2800 may be disposed between the first interconnection layer 800 and the third substrate 2000. The second interconnection layer 1800 of the circuit chip 20 may be provided under the third substrate 2000.

Driving transistors 2700 may be provided on a top surface of the third substrate 2000. The driving transistors 2700 may include the conversion gain transistor Cx, the reset transistor Rx, the source follower transistor Sx, and the selection transistor Ax, described with reference to FIG. 1. In other words, according to the present embodiments, the photoelectric conversion region PD, the transfer transistor Tx, and the floating diffusion region FD of FIG. 1 may be provided in or on the first substrate 100 of the sensor chip 10. The conversion gain transistor Cx, the reset transistor Rx, the source follower transistor Sx, and the selection transistor Ax of FIG. 1 may be provided on the third substrate 2000 of the intermediate chip 30.

The third interconnection layer 2800 may include fourth interlayer insulating layers 2820 and third conductive structures 2830. The third conductive structures 2830 may be provided between the fourth interlayer insulating layers 2820 and/or in the fourth interlayer insulating layers 2820. The third conductive structures 2830 may be electrically connected to the driving transistors 2700. The third conductive structures 2830 may include contacts, interconnection lines, and vias.

The sensor chip 10 may include the first connection pad 850. The first connection pad 850 may be exposed at the bottom surface of the sensor chip 10. The first connection pad 850 may be disposed in the lowermost second interlayer insulating layer 820. The first connection pad 850 may be electrically connected to the first conductive structure 830.

The intermediate chip 30 may include a third connection pad 2850. The third connection pad 2850 may be exposed at a top surface of the intermediate chip 30. The third connection pad 2850 may be disposed in an uppermost fourth interlayer insulating layer 2820. The third connection pad 2850 may be electrically connected to the driving transistors 2700. The third connection pad 2850 may include a conductive material such as a metal. For some examples, the third connection pad 2850 may include copper. For certain examples, the third connection pad 2850 may include aluminum, tungsten, titanium, and/or any alloy thereof.

The intermediate chip 30 may be connected to the sensor chip 10 by direct bonding. For example, the first connection pad 850 and the third connection pad 2850 may be vertically aligned with each other, and the first connection pad 850 and the third connection pad 2850 may be in contact with each other. Thus, the third connection pad 2850 may be bonded directly to the first connection pad 850. As a result, the driving transistors 2700 of the intermediate chip 30 may be electrically connected to the floating diffusion regions FD of the sensor chip 10 through the first and third connection pads 850 and 2850.

The second interlayer insulating layer 820 may be adhered directly to the fourth interlayer insulating layer 2820. In this case, chemical bonds may be formed between the second interlayer insulating layer 820 and the fourth interlayer insulating layer 2820.

The intermediate chip 30 may further include through-vias 2840 penetrating the third substrate 2000. Each of the through-vias 2840 may electrically connect the third interconnection layer 2800 to the second interconnection layer 1800. In other words, the intermediate chip 30 and the circuit chip 20 may be electrically connected to each other through the through-vias 2840.

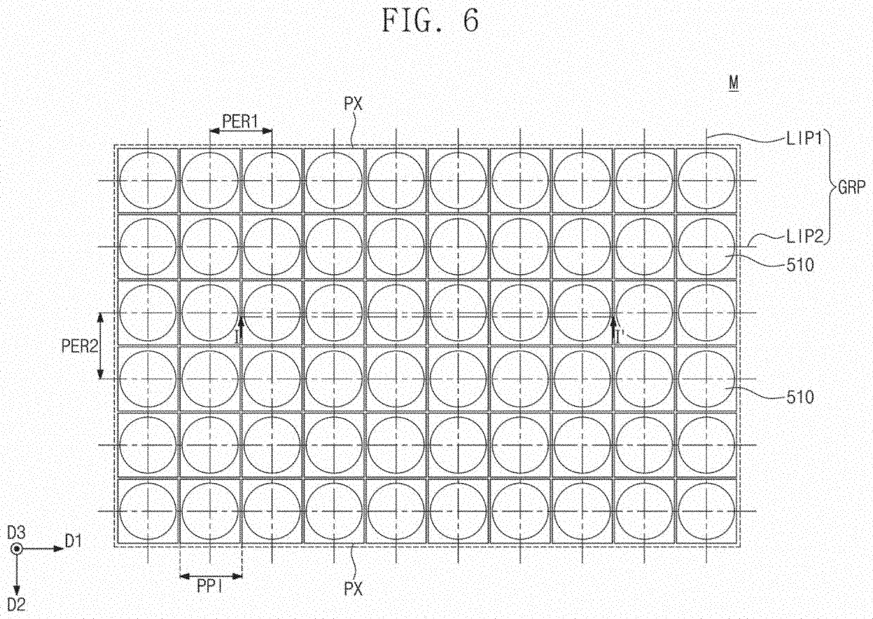

FIG. 6 is an enlarged plan view of a region ‘M’ of FIG. 2 to illustrate an image sensor according to some example embodiments of the inventive concepts. FIG. 7 is a cross-sectional view taken along a line I-I′ of FIG. 6. In the present embodiments, the descriptions to the same technical features as mentioned above with reference to FIGS. 1 to 5 will be omitted and differences between the present embodiments and the above embodiments of FIGS. 1 to 5 will be mainly described, for the purpose of ease and convenience in explanation.

Referring to FIGS. 6 and 7, an image sensor may include a first substrate 100. The image sensor may further include an insulating layer 400, color filters CF, a fence pattern 300, and a micro lens layer 500, which are provided on the first surface 100a of the first substrate 100. In the present embodiments, illustration of components under the first substrate 100 is omitted, and the components under the first substrate 100 may be the same as described above with reference to FIGS. 3 to 5.

The pixel array region APS of the first substrate 100 may include the pixel regions PX arranged two-dimensionally. The pixel regions PX may have the same size (or area). Each of the pixel regions PX may include the photoelectric conversion region PD.

An isolation pattern 200 having a grid shape may be provided in the first substrate 100. The isolation pattern 200 may define the pixel regions PX. In some embodiments, the isolation pattern 200 may include a first isolation pattern 210 and a second isolation pattern 220.

The first isolation pattern 210 may be disposed between the second isolation pattern 220 and the first substrate 100. For example, the first isolation pattern 210 may include an insulating material such as silicon oxide. The second isolation pattern 220 may include a conductive material such as doped poly-silicon or a metal. For example, as described above with reference to FIG. 3, the second isolation pattern 220 adjacent to the pad region PDR may be electrically connected to the first conductive pattern 911.

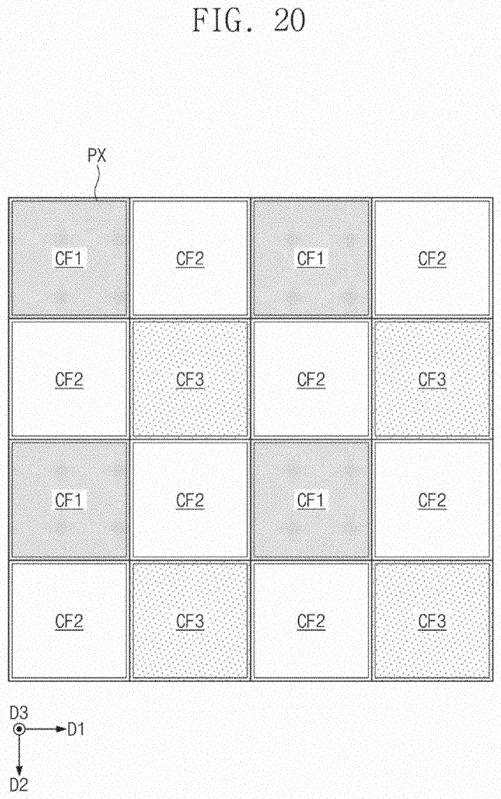

The insulating layer 400 may be provided on the first surface 100a of the first substrate 100. The color filter CF may be provided on each of the pixel regions PX. The color filter CF may be provided on the insulating layer 400. The color filter CF may be a red filter, a green filter, a blue filter, a white color filter, or a transparent filter. Arrangements of the color filters CF will be described later with reference to FIGS. 20 to 22.

The fence pattern 300 may be provided between the color filters CF adjacent to each other. A protective layer 470 may be disposed between the fence pattern 300 and the color filters CF.

The micro lens layer 500 including micro lenses 510 may be provided on the color filters CF. The micro lens layer 500 may include a flat layer 505 and the micro lenses 510 on the flat layer 505. In some embodiments, the flat layer 505 may include the same material as the micro lenses 510. Thus, a boundary between the flat layer 505 and the micro lenses 510 may be omitted. In certain embodiments, the flat layer 505 may include a different material from that of the micro lenses 510.

A lens coating layer 530 may be provided on the micro lenses 510. The micro lenses 510 may be provided on the color filters CF, respectively. The micro lenses 510 may be two-dimensionally arranged. In detail, the micro lenses 510 may have the same size. The micro lenses 510 may be uniformly arranged at a first pitch in the first direction D1. The micro lenses 510 may be arranged at a second pitch in the second direction D2. The first pitch and the second pitch may be equal to each other. Each of the first pitch and the second pitch may be equal to a pixel pitch PPI of the pixel regions PX.

Each of the micro lenses 510 according to the present embodiments may have the same size, the same curvature and the same shape, and may include the same material. In the inventive concepts, the micro lenses having the same size may mean that diameters of the micro lenses are equal to each other and heights of the micro lenses are equal to each other. In the inventive concepts, the micro lenses having the same curvature may mean that curvature radiuses of the micro lenses are equal to each other. In the inventive concepts, the micro lenses including the same material may mean that the micro lenses are formed of the same material to have the same refractive index. In the inventive concepts, the micro lenses having the same shape may mean that the micro lenses have the same area and the same planar shape.

Since the micro lenses 510 are two-dimensionally arranged, the micro lenses 510 may constitute or form a grating pattern GRP when viewed in a plan view. The grating pattern GRP may include a plurality of first line patterns LIP1, each of which is formed by the micro lenses 510 arranged in the second direction D2, and a plurality of second line patterns LIP2, each of which is formed by the micro lenses 510 arranged in the first direction D1. The first line patterns LIP1 may extend in the second direction D2, and the second line patterns LIP2 may intersect the first line patterns LIP1 and may extend in the first direction D1.

A pitch of the first line patterns LIP1 may be equal to a first arrangement period PER1 of the micro lenses 510 in the first direction D1. A pitch of the second line patterns LIP2 may be equal to a second arrangement period PER2 of the micro lenses 510 in the second direction D2.

In the present embodiments, the first arrangement period PER1 may be equal to the second arrangement period PER2. Each of the first arrangement period PER1 and the second arrangement period PER2 may be equal to the pixel pitch PPI.

Referring again to FIGS. 6 and 7, the grating pattern GRP formed by the micro lenses 510 may generate first diffraction light DFL1 from incident light ICL. More particularly, the grating pattern GRP may function as a diffraction grating, and thus the first diffraction light DFL1 may be generated by constructive and destructive interference on the micro lens 510. The first diffraction light DFL1 may have a first diffraction angle θ1 with respect to the incident light ICL.

The first diffraction light DFL1 may be reflected at an IR filter IRF disposed above the micro lenses 510 and then may be incident to another pixel region PX. The first diffraction light DFL1 may be reflected at a top surface of the infrared (IR) filter IRF and then may be incident to another pixel region PX. The first diffraction light DFL1 may be reflected at a module lens MDL disposed above the IR filter IRF and then may be incident to another pixel region PX.

As a result, the first diffraction light DFL1 may be incident again to other pixel regions PX, and thus a noise signal may be generated. The noise signal may be shown as a petal-shaped pattern in the output (e.g., an image) of the image sensor. A phenomenon that the petal-shaped pattern corresponding to the noise signal is generated may be referred to as petal flare.

In the image sensor according to the present embodiments, the grating pattern GRP of the micro lenses 510 may have the first and second arrangement periods PER1 and PER2 having very small values. As an arrangement period decreases, a diffraction order of diffraction light generated from the incident light ICL may decrease, and a diffraction angle of the diffraction light may increase.

For example, in the present embodiments, the first diffraction light DFL1 having a first diffraction order with respect to the incident light ICL may be strongly generated solely, and the first diffraction light DFL1 may have the first diffraction angle θ1 greater than 70 degrees. Thus, the aforementioned petal flare may be strongly generated in the image sensor of the present embodiments.

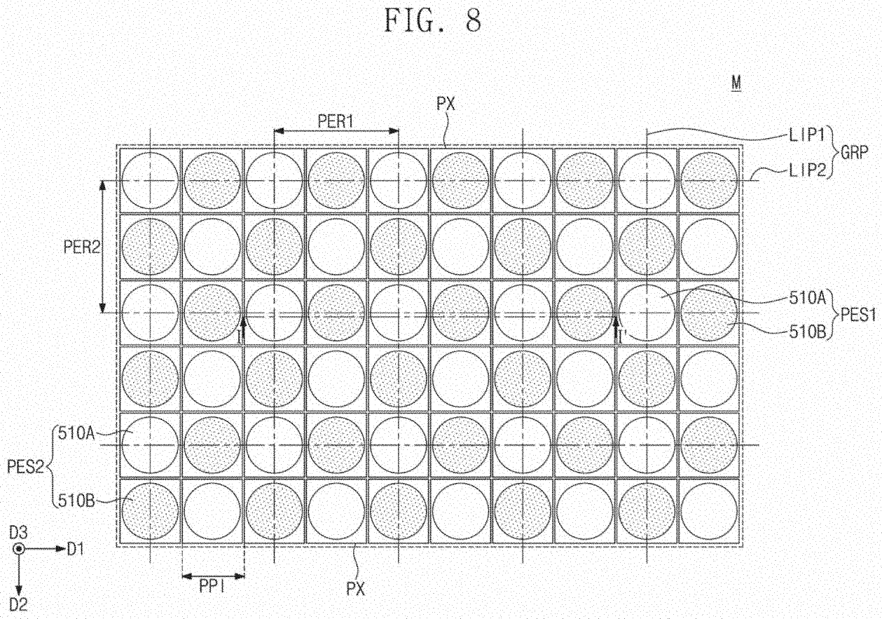

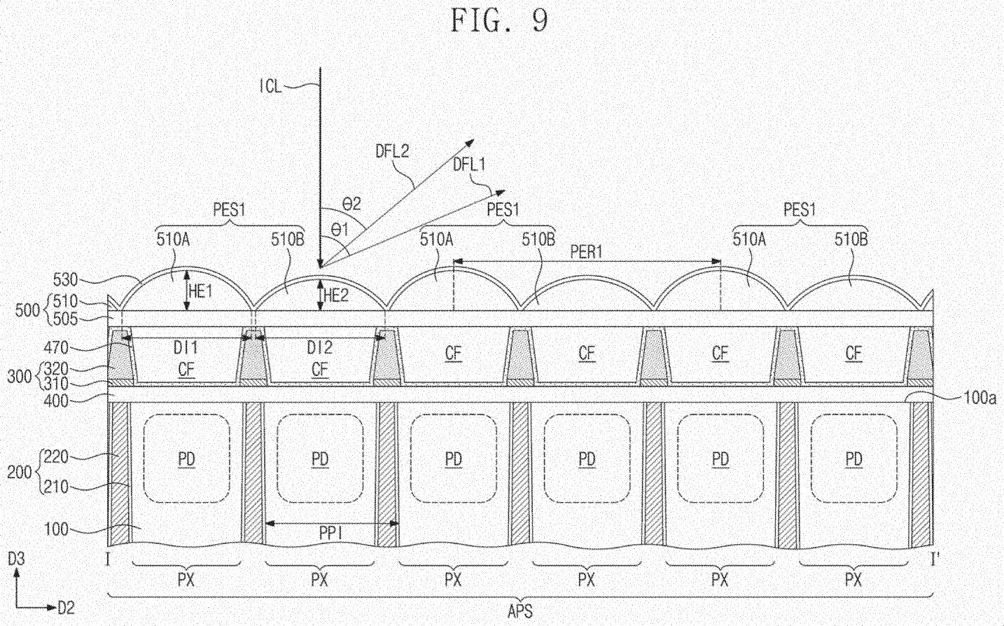

FIG. 8 is an enlarged plan view of the region ‘M’ of FIG. 2 to illustrate an image sensor according to some example embodiments of the inventive concepts. FIG. 9 is a cross-sectional view taken along a line I-I′ of FIG. 8. In the present embodiments, the descriptions to the same technical features as mentioned above with reference to FIGS. 6 and 7 will be omitted and differences between the present embodiments and the above embodiments of FIGS. 6 and 7 will be mainly described, for the purpose of ease and convenience in explanation.

Referring to FIGS. 8 and 9, micro lenses 510 according to the inventive concepts may include first micro lenses 510A and second micro lenses 510B. The first and second micro lenses 510A and 510B may be alternately arranged in the first direction D1. A repeat structure of the first and second micro lenses 510A and 510B in the first direction D1 may include a first period structure PES1. The first period structure PES1 may include a single first micro lens 510A and a single second micro lens 510B, which are arranged side by side in the first direction D1. A plurality of the first period structures PES1 may be arranged in the first direction D1.

The first and second micro lenses 510A and 510B may be alternately arranged in the second direction D2. A repeat structure of the first and second micro lenses 510A and 510B in the second direction D2 may include a second period structure PES2. The second period structure PES2 may include a single first micro lens 510A and a single second micro lens 510B, which are arranged side by side in the second direction D2. A plurality of the second period structures PES2 may be arranged in the second direction D2.

The first micro lens 510A and the second micro lens 510B may be different from each other. In the present specification, that the first and second micro lenses 510A and 510B are different from each other may mean that sizes, curvatures, materials and/or shapes thereof are different from each other. For example, the that first and second micro lenses 510A and 510B may be different from each in at least one of a size, a curvature, a material, and a shape.

In the inventive concepts, the micro lenses having different sizes may mean that diameters of the micro lenses are different from each other and heights of the micro lenses are different from each other. In the inventive concepts, the micro lenses having different curvatures may mean that curvature radiuses of the micro lenses are different from each other. In the inventive concepts, the micro lenses having different materials may mean that the micro lenses include materials having different refractive indexes. In the inventive concepts, the micro lenses having different shapes may mean that the micro lenses have different areas and different planar shapes.

For example, referring again to FIG. 9, the size of the first micro lens 510A may be different from the size of the second micro lens 510B. The first micro lens 510A may have a first diameter DI1, and the second micro lens 510B may have a second diameter DI2 less than the first diameter DI1. The first micro lens 510A may have a first height HE′. The first height HE1 may be a vertical distance from a top surface of the flat layer 505 to a crest of the first micro lens 510A. The second micro lens 510B may have a second height HE2 less than the first height HE1. The second height HE2 may be a vertical distance from a top surface of the flat layer 505 to a crest of the second micro lens 510B.

Referring again to FIGS. 6 and 7, the same micro lenses 510 may be arranged in the first direction D1 in the pattern of A A A A A A . . . , and thus the first arrangement period PER1 of the grating pattern GRP may be equal to a pitch of the micro lenses 510. The second arrangement period PER2 of the grating pattern GRP may also be equal to the pitch of the micro lenses 510.

Referring again to FIGS. 8 and 9, the first and second micro lenses 510A and 510B different from each other may be arranged in the first direction D1 in the pattern of A B A B A B . . . , and thus a first arrangement period PER1 of a grating pattern GRP to be described later may be increased as compared with the first arrangement period PER1 of FIGS. 6 and 7. For example, the first arrangement period PER1 of the present embodiments may be equal to a pitch of the first period structures PES1 (A B) arranged in the pattern of (A B) (A B) (A B) . . . .

The first and second micro lenses 510A and 510B different from each other may be arranged in the second direction D2 in the pattern of ABABA B . . . , and thus a second arrangement period PER2 of the grating pattern GRP to be described later may be increased as compared with the second arrangement period PER2 of FIGS. 6 and 7. For example, the second arrangement period PER2 of the present embodiments may be equal to a pitch of the second period structures PES2 (A B) arranged in the pattern of (A B) (A B) (A B) . . . .

The first and second period structures PES1 and PES2 may be two-dimensionally arranged to constitute or form the grating pattern GRP. In other words, the grating pattern GRP of the present embodiments may be defined by the first and second period structures PES1 and PES2, not the micro lenses 510.

A pitch of first line patterns LIP1 of the present embodiments may be equal to the pitch of the first period structures PES1 in the first direction D1, i.e., the first arrangement period PER1. A pitch of second line patterns LIP2 of the present embodiments may be equal to the pitch of the second period structures PES2 in the second direction D2, i.e., the second arrangement period PER2.

The first arrangement period PER1 may be the pitch of the first period structures PES1 in the first direction D1, not the pitch of the micro lenses 510 in the first direction D1. Thus, the first arrangement period PER1 in the present embodiments may be about twice the first arrangement period PER1 described above in FIGS. 6 and 7. The first arrangement period PER1 of the present embodiments may be about twice the pixel pitch PPI.

The second arrangement period PER2 may be the pitch of the second period structures PES2 in the second direction D2, not the pitch of the micro lenses 510 in the second direction D2. Thus, the second arrangement period PER2 in the present embodiments may be about twice the second arrangement period PER2 described above in FIGS. 6 and 7. The second arrangement period PER2 of the present embodiments may be about twice the pixel pitch PPI.

The grating pattern GRP formed by the micro lenses 510 of the present embodiments may generate first diffraction light DFL1 and second diffraction light DFL2 from incident light ICL. The first diffraction light DFL1 may have a first diffraction angle θ1 with respect to the incident light ICL, and the second diffraction light DFL2 may have a second diffraction angle θ2 with respect to the incident light ICL. The grating pattern GRP according to the present embodiments may have the first and second arrangement periods PER1 and PER2, which are about two times greater than those of the grating pattern GRP described above in FIGS. 6 and 7. Thus, a diffraction order of the diffraction light generated from the incident light ICL may increase, and a diffraction angle of the diffraction light may decrease.

For example, in the present embodiments, the first diffraction light DFL1 having a first diffraction order and the second diffraction light DFL2 having a second diffraction order with respect to the incident light ICL may be generated. Since two diffraction lights are generated from the single incident light ICL, an intensity of each of the diffraction lights may be less than an intensity of the first diffraction light DFL1 of FIG. 7. In addition, since the second diffraction light DFL2 has a second diffraction angle θ2 less than 70 degrees, an area of a region affected by the second diffraction light DFL2 may be reduced.

In the image sensor according to the present embodiments, the arrangement period of the grating pattern GRP may be increased to scatter the diffraction light generated from the incident light and to reduce the intensity thereof. As a result, petal flare may be small and weakly generated to reduce visibility of the petal flare. Thus, in the present embodiments of the inventive concepts, the limitations described above in FIGS. 6 and 7 may be solved by increasing the arrangement period of the grating pattern GRP.

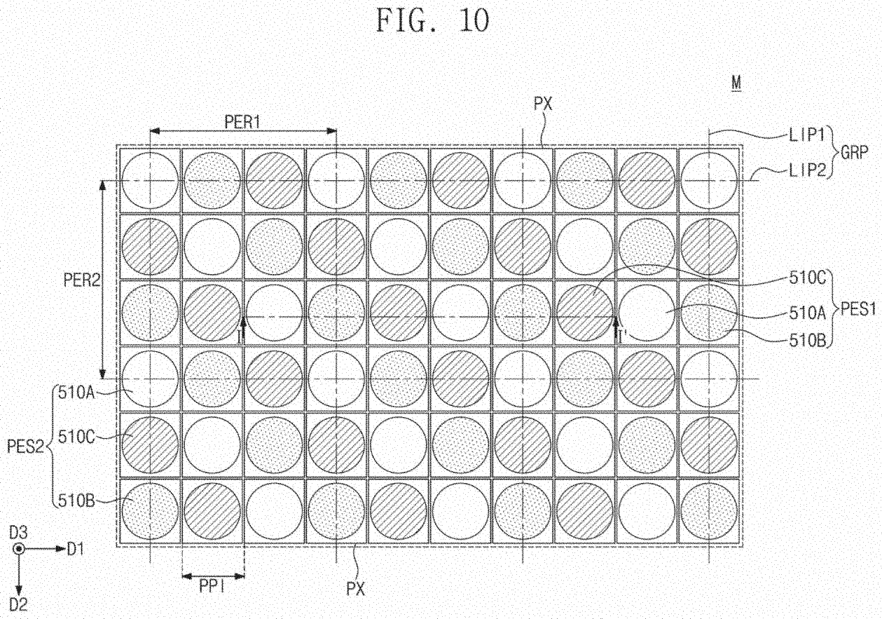

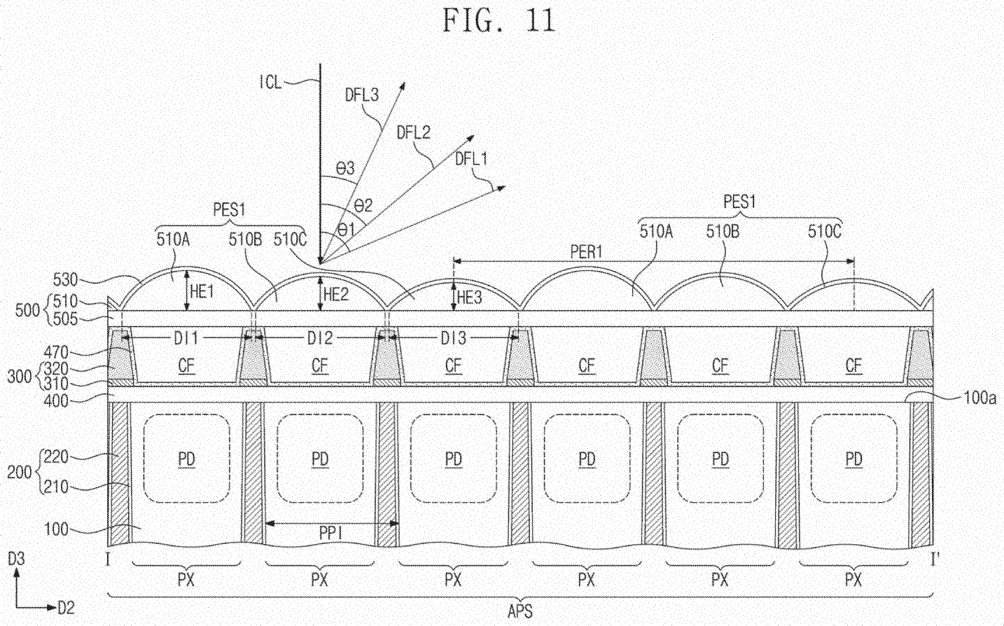

FIG. 10 is an enlarged plan view of the region ‘IVY of FIG. 2 to illustrate an image sensor according to some example embodiments of the inventive concepts. FIG. 11 is a cross-sectional view taken along a line I-I’ of FIG. 10. In the present embodiments, the descriptions to the same technical features as mentioned above with reference to FIGS. 8 and 9 will be omitted and differences between the present embodiments and the above embodiments of FIGS. 8 and 9 will be mainly described, for the purpose of ease and convenience in explanation.

Referring to FIGS. 10 and 11, micro lenses 510 according to the inventive concepts may include first micro lenses 510A, second micro lenses 510B, and third micro lenses 510C.

The first to third micro lenses 510A, 510B, and 510C may be alternately arranged in the first direction D1. A repeat structure of the first to third micro lenses 510A, 510B, and 510C in the first direction D1 may include a first period structure PES1. The first period structure PES1 may include a single first micro lens 510A, a single second micro lens 510B, and a single third micro lens 510C, which are arranged side by side in the first direction D1. A plurality of the first period structures PES1 may be arranged in the first direction D1.

The first to third micro lenses 510A, 510B, and 510C may be alternately arranged in the second direction D2. A repeat structure of the first to third micro lenses 510A, 510B, and 510C in the second direction D2 may include a second period structure PES2. The second period structure PES2 may include a single first micro lens 510A, a single second micro lens 510B, and a single third micro lens 510C, which are arranged side by side in the second direction D2. A plurality of the second period structures PES2 may be arranged in the second direction D2.

The first to third micro lenses 510A, 510B, and 510C may be different from each other. For example, the first to third micro lenses 510A, 510B, and 510C may have different diameters and different heights. The first micro lens 510A may have a first diameter DI1, the second micro lens 510B may have a second diameter DI2 less than the first diameter DI1, and the third micro lens 510C may have a third diameter DI3 less than the second diameter DI2. The first micro lens 510A may have a first height HE1, the second micro lens 510B may have a second height HE2 less than the first height HE1, and the third micro lens 510C may have a third height HE3 less than the second height HE2. The first, second, and third heights HE1, HE2, and HE3 may be vertical distances from a top surface of the flat layer 505 to crests of the first, second, and third micro lenses 510A, 510B, and 510C, respectively.

The first and second period structures PES1 and PES2 may be two-dimensionally arranged to constitute or form a grating pattern GRP. A pitch of first line patterns LIP1 of the present embodiments may be equal to a pitch of the first period structures PES1 in the first direction D1, i.e., a first arrangement period PER1. A pitch of second line patterns LIP2 of the present embodiments may be equal to a pitch of the second period structures PES2 in the second direction D2, i.e., a second arrangement period PER2. Each of the first and second arrangement periods PER1 and PER2 of the present embodiments may be about three times the pixel pitch PPI.

The grating pattern GRP formed by the micro lenses 510 of the present embodiments may generate first diffraction light DFL1, second diffraction light DFL2 and third diffraction light DFL3 from incident light ICL. The first diffraction light DFL1 may have a first diffraction angle θ1 with respect to the incident light ICL, the second diffraction light DFL2 may have a second diffraction angle θ2 with respect to the incident light ICL, and the third diffraction light DFL3 may have a third diffraction angle θ3 with respect to the incident light ICL. The grating pattern GRP according to the present embodiments may have the first and second arrangement periods PER1 and PER2, which are about three times greater than those of the grating pattern GRP described above in FIGS. 6 and 7. Thus, a diffraction order of the diffraction light generated from the incident light ICL may increase, and a diffraction angle of the diffraction light may decrease.

For example, in the present embodiments, the first diffraction light DFL1 having a first diffraction order, the second diffraction light DFL2 having a second diffraction order, and the third diffraction light DFL3 having a third diffraction order with respect to the incident light ICL may be generated. Since three diffraction lights are generated from the single incident light ICL, an intensity of each of the diffraction lights may be much less than the intensity of the first diffraction light DFL1 of FIG. 7. In addition, since the third diffraction light DFL3 has a third diffraction angle θ3 less than 40 degrees, an area of a region affected by the third diffraction light DFL3 may be reduced.

In the image sensor according to the present embodiments, the arrangement period of the grating pattern GRP may be further increased to increase scatter of the diffraction light generated from the incident light and to further reduce the intensity thereof. As a result, petal flare may be very small and weakly generated to significantly reduce visibility of the petal flare. Thus, in the present embodiments of the inventive concepts, the limitations described above in FIGS. 6 and 7 may be solved by increasing the arrangement period of the grating pattern GRP.

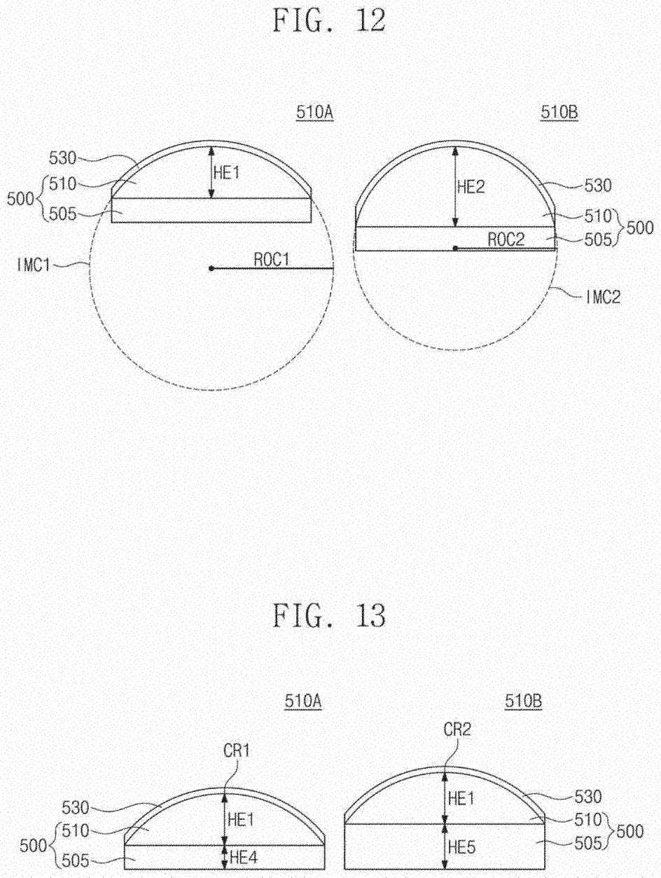

FIGS. 12, 13, and 14 are cross-sectional views illustrating differences between a first micro lens and a second micro lens according to some example embodiments of the inventive concepts.

Referring to FIG. 12, a first micro lens 510A and a second micro lens 510B may have different curvatures. For example, a first imaginary circle IMC1 overlapping with a surface of the first micro lens 510A may be defined. A second imaginary circle IMC2 overlapping with a surface of the second micro lens 510B may be defined. A first radius ROC1 of the first imaginary circle IMC1 may be a first curvature radius of the first micro lens 510A, and a second radius ROC2 of the second imaginary circle IMC2 may be a second curvature radius of the second micro lens 510B.

The first radius ROC1 of the first micro lens 510A may be greater than the second radius ROC2 of the second micro lens 510B. In other words, the curvature of the first micro lens 510A may be less than the curvature of the second micro lens 510B. Since the first micro lens 510A and the second micro lens 510B have the different curvatures, a height HE1 of the first micro lens 510A may be different from a height HE2 of the second micro lens 510B.

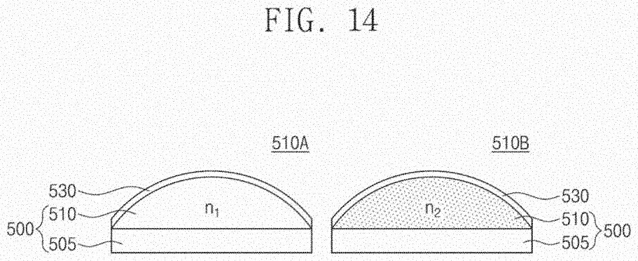

Referring to FIG. 13, a level of a first crest CR1 of a first micro lens 510A may be different from a level of a second crest CR2 of a second micro lens 510B. For example, the level of the first crest CR1 of the first micro lens 510A may be lower than the level of the second crest CR2 of the second micro lens 510B.

The first micro lens 510A and the second micro lens 510B may have the same diameter, the same height, and the same curvature. Meanwhile, a height HE4 (or a thickness) of the flat layer 505 under the first micro lens 510A may be less than a height HE5 (or a thickness) of the flat layer 505 under the second micro lens 510B. Thus, the level of the first crest CR1 of the first micro lens 510A may be lower than the level of the second crest CR2 of the second micro lens 510B.

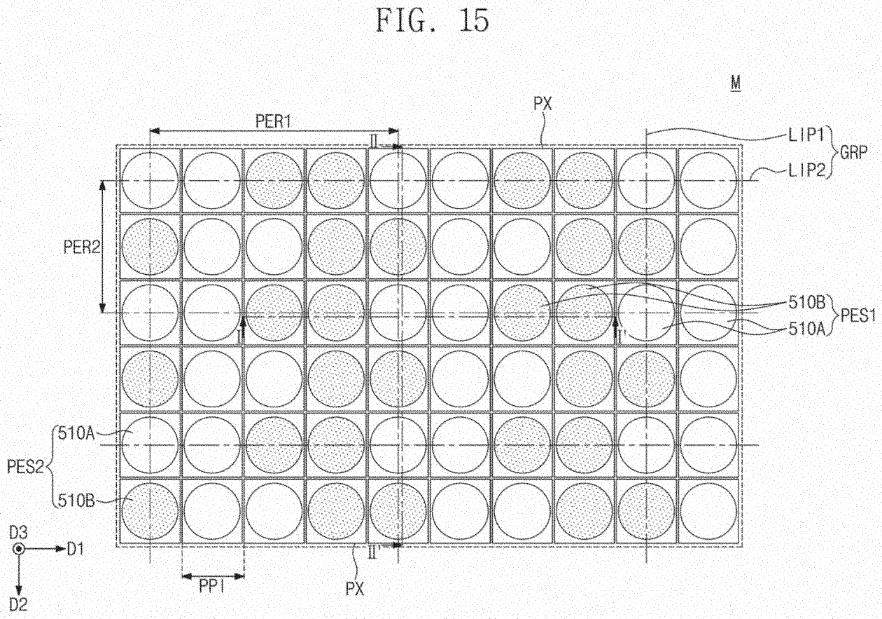

Referring to FIG. 14, a first micro lens 510A and a second micro lens 510B may include different materials. More particularly, the first micro lens 510A and the second micro lens 510B may have the same diameter, the same height, and the same curvature. However, a first refractive index n1 of the first micro lens 510A may be different from a second refractive index n2 of the second micro lens 510B.

As described with reference to FIGS. 12 to 14, in the inventive concepts, that the micro lenses are different from each other may mean that the sizes, the curvatures, the materials and/or the shapes of the micro lenses are different from each other. For example, the micro lenses may be different from each in at least one of a size, a curvature, a material, and a shape. In some embodiments of the inventive concepts, two or more of the sizes, the curvatures, the materials and the shapes of the micro lenses may be different from each other. The embodiments illustrated in FIGS. 12 to 14 may be provided in any combination in any of the embodiments disclosed herein, including those illustrated in FIGS. 1 to 10 and FIGS. 15 to 22.

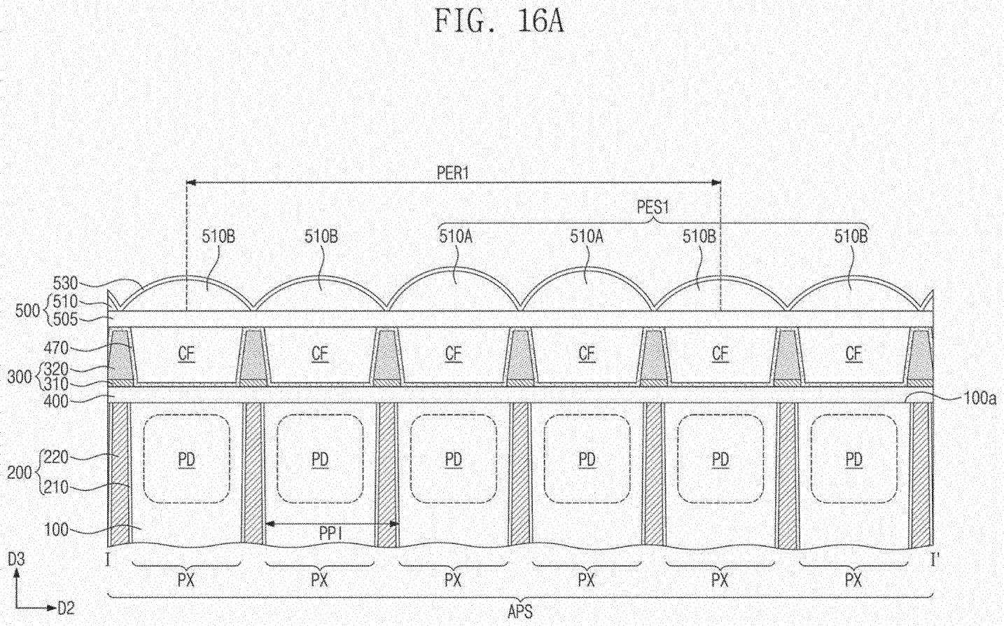

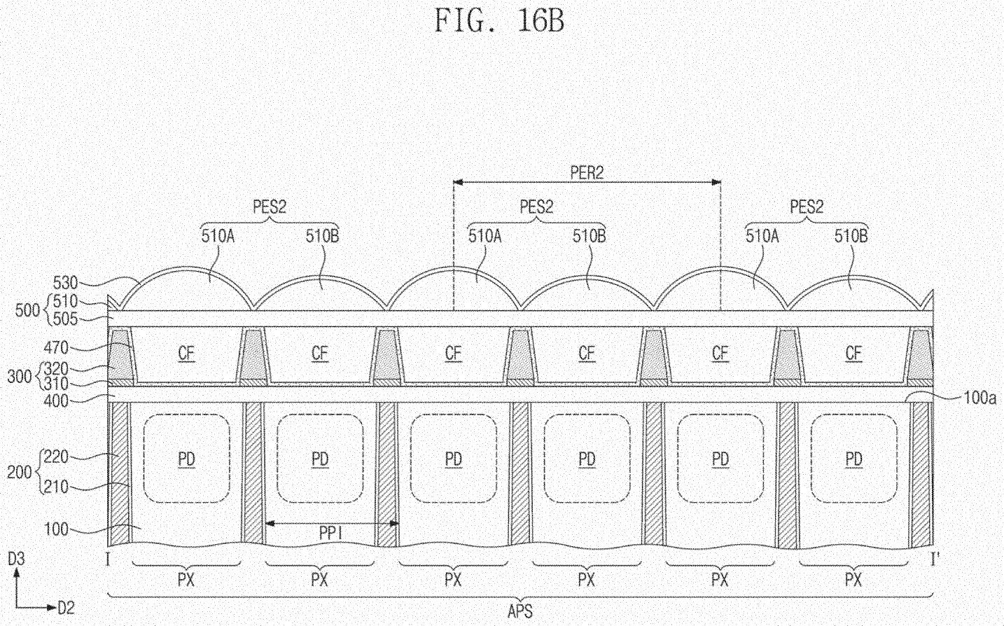

FIG. 15 is an enlarged plan view of the region ‘IVY of FIG. 2 to illustrate an image sensor according to some example embodiments of the inventive concepts. FIG. 16A is a cross-sectional view taken along a line I-I’ of FIG. 15. FIG. 16B is a cross-sectional view taken along a line II-IF of FIG. 15.

Referring to FIGS. 15, 16A and 16B, a first period structure PES1 may include two first micro lenses 510A and two second micro lenses 510B, which are sequentially arranged in the first direction D1. A first arrangement period PER1 of the first period structures PES1 may be about four times the pixel pitch PPI. In other words, first line patterns LIP1 of a grating pattern GRP of the present embodiments may have a period (or pitch) of 4×PPI.

A second period structure PES2 may include a single first micro lens 510A and a single second micro lens 510B, which are sequentially arranged in the second direction D2. A second arrangement period PER2 of the second period structures PES2 may be about twice the pixel pitch PPI. In other words, second line patterns LIP2 of the grating pattern GRP of the present embodiments may have a period (or pitch) of 2×PPI.

As shown in the present embodiments, the first period structure PES1 and the second period structure PES2 of the grating pattern GRP may be different from each other. The first period structure PES1 may be N×PPI, the second period structure PES2 may be M×PPI, each of ‘N’ and ‘M’ may be an integral number of 2 or more, and ‘N’ and ‘M’ may be equal to or different from each other.

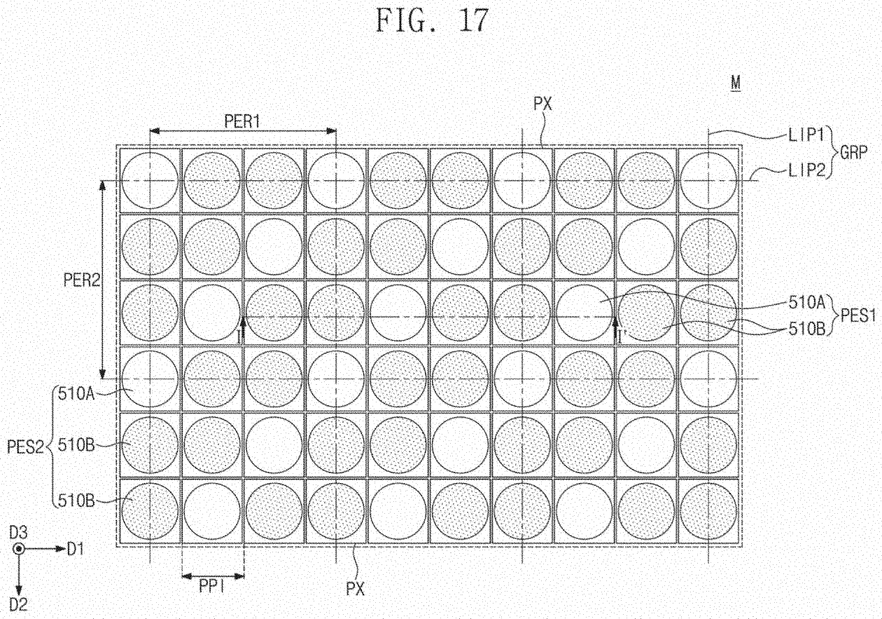

FIG. 17 is an enlarged plan view of the region ‘M’ of FIG. 2 to illustrate an image sensor according to some example embodiments of the inventive concepts. Referring to FIG. 17, a first period structure PES1 may include a single first micro lens 510A and two second micro lenses 510B, which are sequentially arranged in the first direction D1. A first arrangement period PER1 of the first period structures PES1 may be about three times the pixel pitch PPI. In other words, first line patterns LIP1 of a grating pattern GRP of the present embodiments may have a period (or pitch) of 3×PPI.

A second period structure PES2 may include a single first micro lens 510A and two second micro lenses 510B, which are sequentially arranged in the second direction D2. A second arrangement period PER2 of the second period structures PES2 may be about three times the pixel pitch PPI. In other words, second line patterns LIP2 of the grating pattern GRP of the present embodiments may have a period (or pitch) of 3×PPI.

Referring again to FIGS. 15 and 17, the first period structure PES1 according to the inventive concepts may include at least two first micro lenses 510A arranged side by side and/or at least two second micro lenses 510B arranged side by side. The first period structure PES1 may include N first micro lenses 510A and M second micro lenses 510B, which are sequentially arranged. Each of ‘N’ and ‘M’ may be an integral number of 1 to 5. For example, in the first period structure PES1 of FIG. 15, ‘N’ may be 2, and ‘M’ may be 2. For example, in the first period structure PES1 of FIG. 17, ‘N’ may be 1, and ‘M’ may be 2. For example, in the first period structure PES1 of FIG. 8, ‘N’ may be 1, and ‘M’ may be 1. Descriptions to the second period structure PES2 may be substantially the same as the above descriptions to the first period structure PES1.

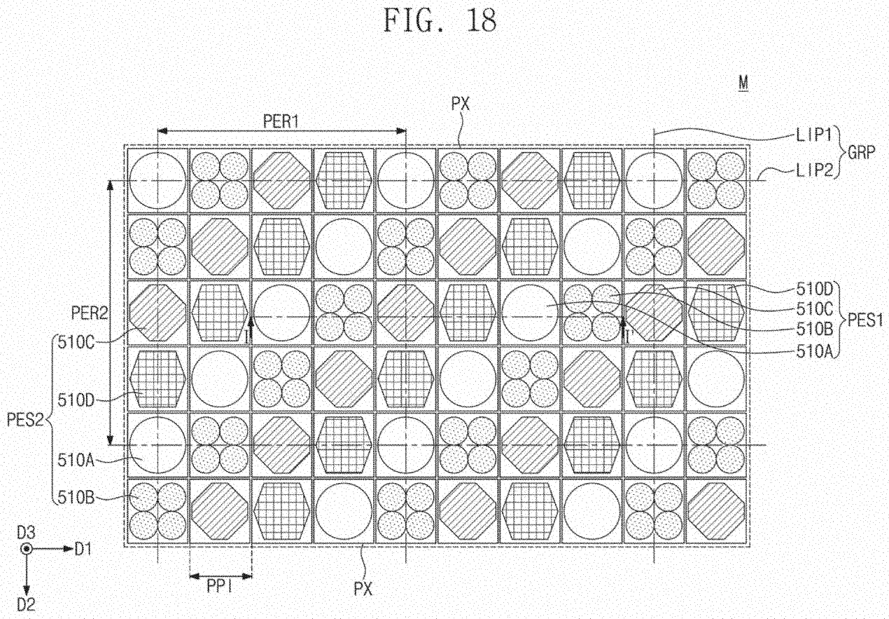

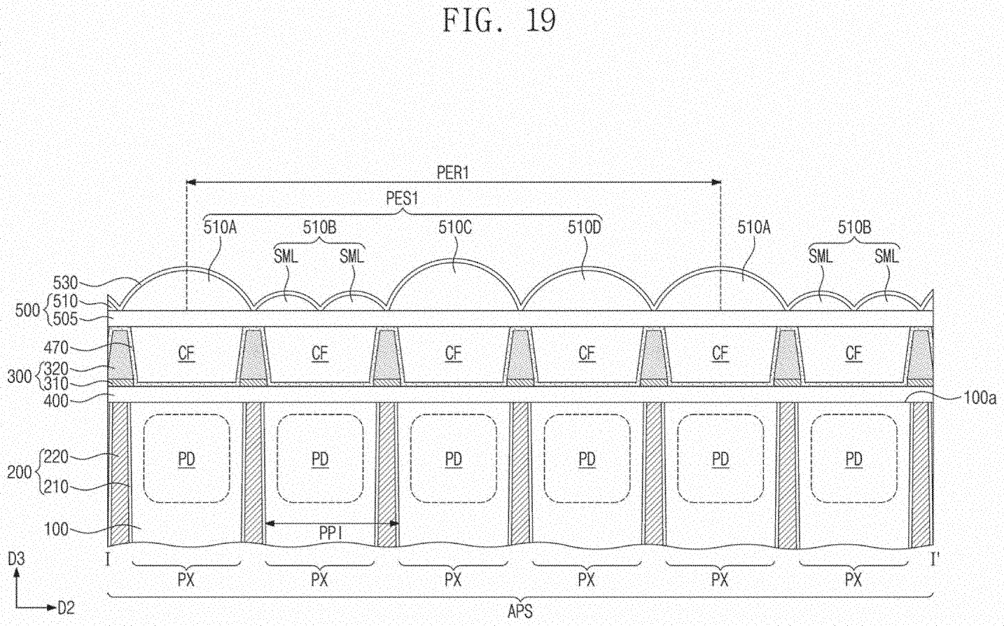

FIG. 18 is an enlarged plan view of the region ‘M’ of FIG. 2 to illustrate an image sensor according to some example embodiments of the inventive concepts. FIG. 19 is a cross-sectional view taken along a line I-I′ of FIG. 18.

Referring to FIGS. 18 and 19, a first period structure PES1 may include a first micro lens 510A, a second micro lens 510B, a third micro lens 510C, and a fourth micro lens 510D, which are sequentially arranged in the first direction D1. A first arrangement period PER1 of the first period structures PES1 may be about four times the pixel pitch PPI. In other words, first line patterns LIP1 of a grating pattern GRP of the present embodiments may have a period (or pitch) of 4×PPI.

A second period structure PES2 may include the first micro lens 510A, the second micro lens 510B, the third micro lens 510C and the fourth micro lens 510D, which are sequentially arranged in the second direction D2. A second arrangement period PER2 of the second period structures PES2 may be about four times the pixel pitch PPI. In other words, second line patterns LIP2 of the grating pattern GRP of the present embodiments may have a period (or pitch) of 4×PPI.

The first to fourth micro lenses 510A to 510D according to the present embodiments may have different shapes. More particularly, the first to fourth micro lenses 510A to 510D may have different areas and different planar shapes.

The first micro lens 510A may have a circular planar shape. The second micro lens 510B may include a plurality of sub-lenses SML. The third micro lens 510C may have a polygonal shape, e.g., an octagonal planar shape. The fourth micro lens 510D may have a polygonal shape, e.g., a hexagonal planar shape.

FIGS. 20, 21 and 22 are plan views illustrating arrangements of color filters of image sensors according to some example embodiments of the inventive concepts.

Referring to FIG. 20, color filters CF may include first to third color filters CF1, CF2, and CF3 arranged in the form of a 2×2 array. The 2×2 color filters CF may include a single first color filter CF1, two second color filters CF2, and a single third color filter CF3. The 2×2 color filters CF may be two-dimensionally arranged in the form of a Bayer pattern. For example, the first color filter CF1 may be a red color filter, the second color filters CF2 may be green color filters, and the third color filter CF3 may be a blue color filter.

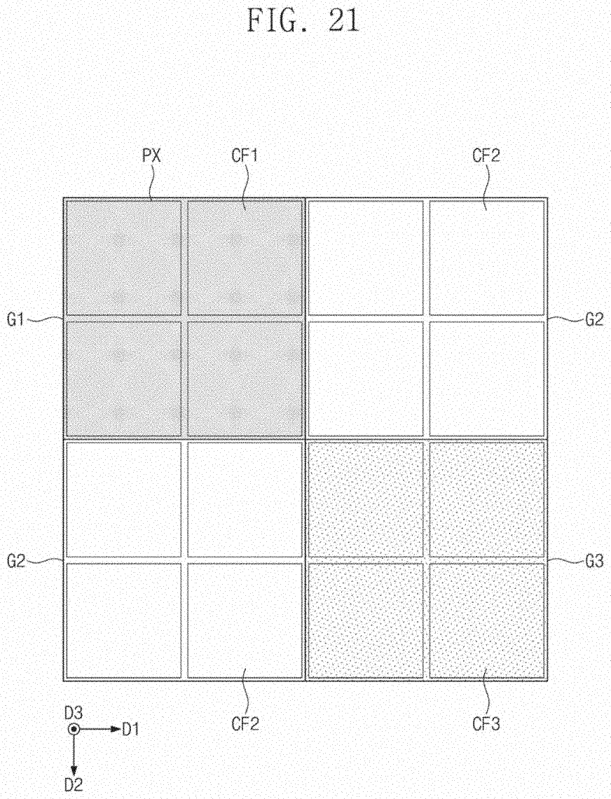

Referring to FIG. 21, first to third pixel groups G1, G2, and G3 may be provided. The first pixel group G1 may sense first light, the second pixel groups G2 may sense second light, and the third pixel group G3 may sense third light.

Each of the first to third pixel groups G1, G2, and G3 may include N×M pixel regions PX in an N×M array. The ‘N’ and the ‘M’ may be each independently an integral number greater than 1. In the present embodiments, each of the ‘N’ and the ‘M’ may be 2, and the image sensor may have a pixel array of a 2×2 tetra structure.

The first pixel group G1 may include a first color filter CF1, each of the second pixel groups G2 may include a second color filter CF2, and the third pixel group G3 may include a third color filter CF3. For example, the first color filter CF1 may be a red color filter, the second color filter CF2 may be a green color filter, and the third color filter CF3 may be a blue color filter.

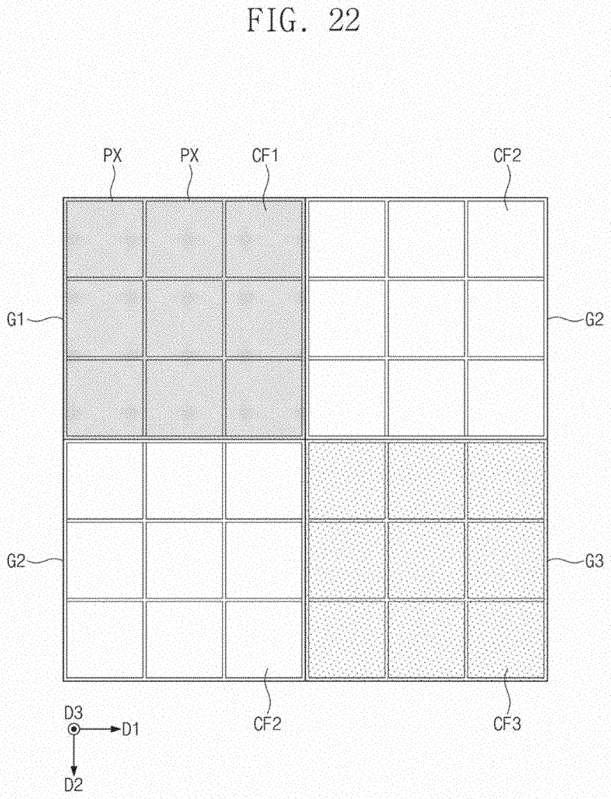

Referring to FIG. 22, each of first to third pixel groups G1, G2, and G3 may include N×M pixel regions PX arranged in the form of an N×M array. In the present embodiments, each of the ‘N’ and the ‘M’ may be 3, and the image sensor may have a pixel array of a 3 λ3 Nona structure.

According to the embodiments of the inventive concepts, the repeated period of the grating pattern of generating diffraction light may be increased using the repeated period structure having different micro lenses while not changing a pixel size. Thus, in the image sensor according to the inventive concepts, the visibility of the petal flare may be reduced, and a noise phenomenon generated in an image (output) by the petal flare may be solved.

While the embodiments of the inventive concepts have been particularly shown and described, it will be understood by one of ordinary skill in the art that variations in form and detail may be made therein without departing from the spirit and scope of the attached claims.

What is claimed is:

1. An image sensor comprising:
a first substrate including pixel regions, each of the pixel regions comprising a photoelectric conversion region;
color filters provided on the pixel regions, respectively, the color filters provided on a first surface of the first substrate; and
micro lenses provided on the color filters, respectively,
wherein first period structures repeatedly arranged in a first direction are defined by the micro lenses,
wherein each of the first period structures comprises a first micro lens and a second micro lens of the micro lenses,
wherein the first and second micro lenses are different from each other in at least one of a size, a curvature, a material, and a shape, and
wherein a first arrangement period of the first period structures is equal to or greater than twice a pixel pitch of the pixel regions.

2. The image sensor of claim 1,
wherein second period structures repeatedly arranged in a second direction intersecting the first direction are defined by the micro lenses,
wherein each of the second period structures comprises the first micro lens and a second micro lens of the micro lenses,
wherein the second and third micro lenses are the same as each other in the size, the curvature, the material, and the shape, and
wherein a second arrangement period of the second period structures is equal to or greater than twice the pixel pitch.

3. The image sensor of claim 2, wherein the second arrangement period is substantially equal to the first arrangement period.

4. The image sensor of claim 2, wherein the second arrangement period is different from the first arrangement period.

5. The image sensor of claim 2, wherein the first period structures and the second period structures constitute a grating pattern that is configured to generate a plurality of diffraction lights from incident light.

6. The image sensor of claim 1,
wherein a first diameter of the first micro lens is different from a second diameter of the second micro lens, and
wherein a first height of the first micro lens is different from a second height of the second micro lens.

7. The image sensor of claim 1,
wherein the first micro lens includes a first material having a first refractive index, and
wherein the second micro lens includes a second material having a second refractive index different from the first refractive index.

8. The image sensor of claim 1,
wherein a first curvature radius of the first micro lens is different from a second curvature radius of the second micro lens, and
wherein a first height of the first micro lens is different from a second height of the second micro lens.

9. The image sensor of claim 1,
wherein each of the first period structures comprises N first micro lenses and M second micro lenses, which are sequentially arranged in the first direction, and
wherein each of the N and the M is an integral number of 1 to 5.

10. The image sensor of claim 1, further comprising:
transistors provided on a second surface, opposite to the first surface, of the first substrate;
a first interconnection layer on the second surface;
a second substrate; and
a second interconnection layer on the second substrate,
wherein the first interconnection layer and the second interconnection layer are vertically stacked and are electrically connected to each other.

11. An image sensor comprising:
a substrate including pixel regions, each of the pixel regions comprising a photoelectric conversion region;
color filters provided on the pixel regions, respectively, the color filters provided on a first surface of the substrate; and
micro lenses provided on the color filters, respectively,
wherein first period structures repeatedly arranged in a first direction are defined by the micro lenses,
wherein second period structures repeatedly arranged in a second direction intersecting the first direction are defined by the micro lenses,
wherein a first arrangement period of the first period structures is equal to or greater than twice a pixel pitch of the pixel regions, and
wherein a second arrangement period of the second period structures is equal to or greater than twice the pixel pitch.

12. The image sensor of claim 11, wherein the first period structures and the second period structures constitute a grating pattern that is configured to generate a plurality of diffraction lights from incident light.

13. The image sensor of claim 11,
wherein each of the first and second period structures comprises a first micro lens and a second micro lens of the micro lenses, and
wherein the first and second micro lenses are different from each other in at least one of a size, a curvature, a material, and a shape.

14. The image sensor of claim 11, wherein the second arrangement period is substantially equal to the first arrangement period.

15. The image sensor of claim 11, wherein the second arrangement period is different from the first arrangement period.

16. An image sensor comprising:
a circuit chip; and
an image sensor chip stacked on the circuit chip,
wherein the image sensor chip comprises:
a first substrate comprising photoelectric conversion regions therein and having a first surface and a second surface, which are opposite to each other;
an isolation pattern provided in the first substrate to define pixel regions, the photoelectric conversion regions provided in the pixel regions, respectively;
an insulating layer covering the first surface;
color filters on the insulating layer;
a fence pattern dividing the color filters;
a protective layer between the fence pattern and the color filters;
micro lenses provided on the color filters, respectively;
a lens coating layer on the micro lenses;
a device isolation pattern disposed adjacent to the second surface to define an active region;
a buried gate pattern on the second surface; and
a first interconnection layer on the buried gate pattern,
wherein the circuit chip comprises:
a second substrate on which integrated circuits are provided; and
a second interconnection layer on the second substrate,
wherein the first interconnection layer and the second interconnection layer face each other and are electrically connected to each other,
wherein first period structures repeatedly arranged in a first direction are defined by the micro lenses, and
wherein a first arrangement period of the first period structures is equal to or greater than twice a pixel pitch of the pixel regions.

17. The image sensor of claim 16,
wherein second period structures repeatedly arranged in a second direction intersecting the first direction are defined by the micro lenses, and
wherein a second arrangement period of the second period structures is equal to or greater than twice the pixel pitch.

18. The image sensor of claim 17, wherein the first period structures and the second period structures constitute a grating pattern that is configured to generate a plurality of diffraction lights from incident light.

19. The image sensor of claim 16,
wherein each of the first period structures comprises a first micro lens and a second micro lens, adjacent to each other in the first direction, of the micro lenses,
wherein a first diameter of the first micro lens is different from a second diameter of the second micro lens, and
wherein a first height of the first micro lens is different from a second height of the second micro lens.

20. The image sensor of claim 16,
wherein each of the first period structures comprises a first micro lens and a second micro lens, adjacent to each other in the first direction, of the micro lenses,
wherein a first curvature radius of the first micro lens is different from a second curvature radius of the second micro lens, and
wherein a first height of the first micro lens is different from a second height of the second micro lens.
